(19) United States
(12) Patent Application Publication
(10) Pub. No.: US 2026/0047427 A1
(43) Pub. Date: Feb. 12, 2026

(54) CAPACITOR STRUCTURES AND METHODS OF FORMATION

(71) Applicant: Taiwan Semiconductor Manufacturing Company, Ltd., Hsinchu (TW)

(72) Inventors: Tzu Jung TIEN, Hsinchu County (TW); Cheung CHENG, Hsinchu City (TW); Wen-Chih CHIANG, Hsinchu City (TW)

(21) Appl. No.: 18/797,842

(22) Filed: Aug. 8, 2024

(51) Int. Cl. H01L 23/522; H01L 23/528; H01L 23/532

(52) U.S. Cl. CPC H01L 23/5223; H01L 23/5226; H01L 23/5283; H01L 23/53295; H10D 1/042; H10D 1/043; H10D 1/716

(57) ABSTRACT

One or more trench capacitor structures are included in an interconnect layer of a semiconductor device. The processing operations for forming the trench capacitor structures described herein may integrated into the processing operations for forming the interconnect layer. A plurality of columns of a bottom electrode structure of a trench capacitor structure described herein may be built up as a combination of backend conductive structures in the interconnect layer. Portions of interlayer dielectric (ILD) layers of the interconnect layer between the columns of the bottom electrode structure are removed to form trenches of the trench capacitor structure, where the columns define the trenches. The deep trenches may then be lined with a conformal insulator layer and filled with the top electrode structure of the trench capacitor structure.

### BACKGROUND

A semiconductor device may include one or more capacitor structures in an interconnect layer (e.g., a back end of line (BEOL) region or back end region) above a device layer. A capacitor structure may perform and/or support one or more functions in the semiconductor device, such as memory (e.g., dynamic random access memory (DRAM)), charge decoupling, analog-to-digital (A/D) conversion, and/or other functions.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example semiconductor device described herein.

FIGS. 2A and 2B are diagrams of an example implementation of a trench capacitor structure described herein.

FIGS. 3A-3D are diagrams of an example implementation of forming a semiconductor device described herein.

FIGS. 4A-4I are diagrams of an example implementation of forming a trench capacitor structure described herein.

FIG. 5 is a diagram of an example implementation of a trench capacitor structure described herein.

FIG. 6 is a diagram of an example implementation of a trench capacitor structure described herein.

FIG. 7 is a diagram of an example implementation of a trench capacitor structure described herein.

FIG. 8 is a diagram of an example implementation of a trench capacitor structure described herein.

FIGS. 9A-9D are diagrams of an example implementation of forming a trench capacitor structure described herein.

FIG. 10 is a diagram of an example implementation of a trench capacitor structure described herein.

FIGS. 11A-11C are diagrams of an example implementation of a trench capacitor structure described herein.

FIGS. 12A and 12B are diagrams of an example of a semiconductor device described herein.

FIGS. 13A-13F are diagrams of example implementations of top view layouts for subpixels and associated trench capacitor structures of a display pixel of a semiconductor device described herein.

FIG. 14 is a diagram of an example semiconductor device described herein.

FIG. 15 is a diagram of an example semiconductor device described herein.

FIG. 16 is a flowchart of an example process associated with forming a capacitor structure described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A capacitor structure may include a metal-insulator-metal (MIM) structure in which an insulator layer is sandwiched between two conductive electrode layers. The capacitance of the capacitor structure (e.g., the amount of charge that can be stored by the capacitor structure) is directly dependent on the geometry of the conductive electrode layers of the capacitor structure. The greater the area of the conductive electrode layers, the greater the capacitance of the capacitor structure. Thus, increasing the size of the metal electrode layers may increase the capacitance of the capacitor structure.

However, increasing a lateral size of the capacitor structure is in direct contention with semiconductor design principles in the semiconductor industry, in which reducing semiconductor device sizes is pursued to achieve reduced power consumption, to achieve greater operating performance and efficiencies, and/or to enable semiconductor devices to be used in increasingly smaller form factor applications. Reducing the size of a semiconductor device, may result in a need to proportionately reduce the size of a capacitor structure in the semiconductor device, which may result in reduced capacitance and/or reduced performance for the capacitor structure. Moreover, reducing the size of the semiconductor device may increase the difficulty of manufacturing the capacitor structure in that smaller dimensions for the capacitor structure may result in reduced manufacturing tolerances for the capacitor structure, which may result in an increased defect rate in capacitor structures of the semiconductor device. An increased defect rate in capacitor structures of the semiconductor device may result in reduced performance for the semiconductor device and/or may result in an increased rate of scraping semiconductor devices that include capacitor structures, among other examples.

In some implementations described herein, one or more trench capacitor structures are included in an interconnect layer of a semiconductor device. The processing operations for forming the trench capacitor structures described herein may integrated into the processing operations for forming the interconnect layer. As an example, a plurality of columns (or “fingers”) of a bottom electrode structure of a trench capacitor structure described herein may be built up as a combination of backend conductive structures (e.g., interconnect structures and metallization structures) in the interconnect layer. Portions of interlayer dielectric (ILD) layers of the interconnect layer between the columns of the bottom electrode structure are removed to form the trenches of the trench capacitor structure, where the columns define the trenches. In this way, the columns of the bottom electrode structure function as a self-aligned mask for forming the trenches of the structure and enable a high aspect ratio be achieved for the trench capacitor structure. The deep trenches may then be lined with a conformal insulator layer and filled with the top electrode structure of the trench capacitor structure. Since the deep trenches alternate with the columns of the bottom electrode structure, the top electrode structure also includes columns (or “fingers”) that alternate with the columns of the bottom electrode structure.

In this way, the alternating arrangement of the columns of the bottom electrode structure and the columns of the top electrode structure enable the surface area of the top and bottom electrode structures to be increased (e.g., relative to a planar arrangement of top and bottom electrode layers), which may increase the capacitance of the trench capacitor structure with minimal increase to the overall lateral footprint of the trench capacitor structure. In this way, the alternating arrangement of the columns of the bottom electrode and the columns of the top electrode enable the size of the semiconductor device to be decreased, and/or the density of components in the semiconductor device to be increased, while achieving the same or greater capacitance for the trench capacitor structures included in the semiconductor device.

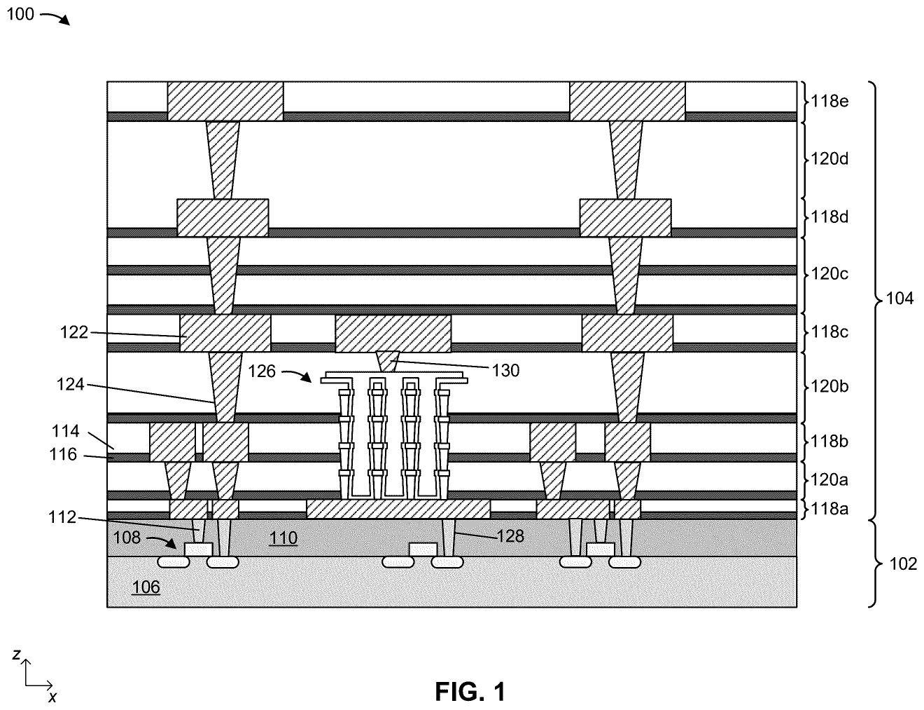

FIG. 1 is a diagram of an example semiconductor device 100 described herein. The semiconductor device 100 may include system on chip (SoC) device, a logic device such as a central processing unit (CPU) or a graphics processing unit (GPU), a memory device (e.g., a high bandwidth memory (HBM) device), an image sensor device (e.g., a complementary metal-oxide-semiconductor (CMOS) image sensor device), a display device (e.g., an organic light emitting diode (OLED) display device), and/or another type of semiconductor device.

As shown in FIG. 1, the semiconductor device 100 may include a device layer 102 and an interconnect layer 104 arranged in a z-direction in the semiconductor device 100. For example, the interconnect layer 104 may be located above the device layer 102. As another example, the interconnect layer 104 may be located below the device layer 102.

The device layer 102 may also be referred to as a front end region or front end of line (FEOL) region of the semiconductor device 100. The interconnect layer 104 may also be referred to a back end region or back end of line (BEOL) region of the semiconductor device 100, and may include conductive structures that are arranged to carry signals and/or provide power distribution throughout the semiconductor device 100. In some implementations, the semiconductor device 100 includes interconnect layers 104 above and below the device layer 102. A first interconnect layer 104 on a first side of the device layer 102 may be used for signal propagation throughout the semiconductor device 100, and a second interconnect layer 104 on an opposing second side of the device layer 102 may be used for power distribution in the semiconductor device 100.

The device layer 102 includes a substrate 106 of the semiconductor device 100. The substrate 106 may correspond to a portion of a semiconductor wafer on which the semiconductor device 100 is formed. The substrate 106 may include a silicon (Si) substrate, a substrate formed of a material including silicon, a III-V compound semiconductor material substrate such as gallium arsenide (GaAs), a silicon on insulator (SOI) substrate, or another type of substrate. The substrate 106 may extend in an x-direction and/or in a y-direction in the semiconductor device 100 such that the top and bottom surfaces of the substrate 106 are approximately orthogonal to the z-direction in the semiconductor device 100.

Integrated circuit devices 108 may be included in and/or on the substrate 106 in the device layer 102 of the semiconductor device 100. The integrated circuit devices 108 may include front end transistor structures (e.g., front end planar transistor structures, front end fin field effect transistor (finFET) structures, front end gate all around (GAA) transistor structures), pixel sensors, capacitors, resistors, inductors, photodetectors, transceivers, transmitters, receives, optical circuits, and/or other types of front end semiconductor devices.

A front end transistor structure may include a plurality of source/drain regions, which may correspond to doped regions of the substrate 106, separated by a channel region in the substrate 106. In some implementations, the source/drain regions are doped with a first type of dopant (e.g., a p-type dopant such as boron (B) and/or gallium (Ga), an n-type dopant such as phosphorous (P) and/or arsenic (As)), and the channel region is doped with a second type of dopant that is different from the first type of dopant. The front end transistor structure may include a gate structure over and/or around the channel region. A gate dielectric layer of the front end transistor structure may be included between the gate structure and the channel region. The gate structure may include a polysilicon gate, a metal gate with a high dielectric constant (high-k) gate dielectric layer such as hafnium oxide (HfOₓ such as HfO₂), and/or another type of gate structure.

A dielectric layer 110 is included over the substrate 106. The dielectric layer 110 includes an ILD layer, an etch stop layer (ESL), and/or another type of dielectric layer. The dielectric layer 110 includes dielectric material(s) that enable various portions of the substrate 106 and/or the integrated circuit devices 108 to be selectively etched or protected from etching, and/or to electrically isolate the integrated circuit devices 108 in the device layer 102. The dielectric layer 110 includes a silicon nitride (SiₓN_{y}), an oxide (e.g., a silicon oxide (SiOₓ) and/or another oxide material), and/or another type of dielectric material. The dielectric layer 110 may extend in the x-direction and/or in the y-direction in the semiconductor device 100. Contact structures 112 (e.g., source/drain contacts, gate contacts) may extend through the dielectric layer 110 and between the integrated circuit devices 108 and the interconnect layer 104. The contacts may electrically connect the integrated circuit devices 108 to the interconnect layer 104. The contact structures 112 may include vias, plugs, and/or another type of elongated electrically conductive structures. The contact structures 112 may include tungsten (W), cobalt (Co), ruthenium (Ru), titanium (Ti), aluminum (Al), and/or gold (Au), among other electrically conductive materials.

The interconnect layer 104 includes a plurality of dielectric layers (e.g., back end dielectric layers) that are arranged in a direction (e.g., the z-direction) that is approximately perpendicular to the top surface of the substrate 106. The dielectric layers may include ILD layers 114 and ESLs 116 that are arranged in an alternating manner in the z-direction. The ILD layers 114 and the ESLs 116 may extend in the x-direction and/or in the y-direction in the semiconductor device 100.

The ILD layers 114 may each include a low dielectric constant (low-k) oxide material such as silicon oxide (SiOₓ) or undoped silicate glass (USG). Additionally and/or alternatively, the ILD layers 114 may each include a boron-containing silicate glass (BSG), a fluorine-containing silicate glass (FSG), tetraethyl orthosilicate (TEOS), hydrogen silsesquioxane (HSQ), and/or another suitable dielectric material. In some implementations, an ILD layer 114 includes an extreme low dielectric constant (ELK) dielectric material having a dielectric constant that is less than approximately 2.5. Examples of ELK dielectric materials include carbon doped silicon oxide (C-SiOₓ), amorphous fluorinated carbon (a-CₓF_{y}), parylene, bis-benzocyclobutenes (BCB), polytetrafluoroethylene (PTFE), a silicon oxycarbide (SiOC) polymer, porous HSQ, porous methyl silsesquioxane (MSQ), porous polyarylether (PAE), and/or porous silicon oxide (SiOₓ), among other examples.

The ESLs 116 may each include a silicon nitride (SiₓN_{y}), silicon carbide (SiC), silicon oxynitride (SiON), and/or another suitable dielectric material. In some implementations, an ILD layer 114 and an ESL 116 include different dielectric materials to provide etch selectivity to enable various structures to be formed in the interconnect layer 104. For example, the ILD layers 114 may each include a low-k dielectric material such as USG, and the ESLs 116 may each include a high-k dielectric material such as silicon nitride (SiₓN_{y}) or silicon carbide (SiC). Additionally and/or alternatively, two or more ESLs 116 may include different materials. For example, one or more first ESLs 116 may include silicon nitride (SiₓN_{y}), and one or more second ESLs 116 may include silicon carbide (SiC).

The interconnect layer 104 includes a plurality of backend conductive structures that are arranged in a plurality of layers. The backend conductive structures may be electrically coupled and/or physically coupled with one or more of the integrated circuit devices 108 in the device layer 102. The backend conductive structures provide electrical routing that enables signals and/or power to be provided to and/or from the integrated circuit devices 108.

The layers of backend conductive structures may include a plurality of layers 118a-118e that are vertically arranged and alternate with a plurality of layers 120a-120d in the z-direction (e.g., vertically alternate). The layers 118a-118e each include a layer of metallization structures 122, and the layers 120a-120d each include a layer of interconnect structures 124.

The layers 118a-118e of metallization structures 122 may be referred to as M-layers. For example, a layer 118a of metallization structures 122 (referred to as a metal-0 (M0) layer) may be located at the bottom of the interconnect layer 104 and may be coupled with the device layer 102. In particular, the metallization structures 122 in the M0 layer may be coupled with the contact structures 112 (e.g., a contact layer referred to as “CO”-layer) of the integrated circuit devices 108 in the device layer 102. A layer 118b of metallization structures 122 (referred to as a metal-1 layer (M1) layer) may be located above the layer 118a of metallization structures 122 in the interconnect layer 104, a layer 118c of metallization structures 122 (referred to as a metal-2 layer (M2) layer) may be located above the a layer 118b of metallization structures 122, and so on.

A layer 120a of interconnect structures 124 (referred to as a via-1 (V0) layer) may be included between the M0 layer and the M1 layer to interconnect the M0 layer and the M1 layer, a layer 120b of interconnect structures 124 (referred to as a via-2 (V1) layer) may be included between the M1 layer and the M2 layer to interconnect the M1 layer and the M2 layer, and so on.

The metallization structures 122 may include a combination of trenches, metallization layers, conductive traces, and/or other types of conductive structures. The interconnect structures 124 may include a combination of vias, interconnects, and/or other types of conductive structures. The metallization structures 122 and the interconnect structures 124 may include one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials. In some implementations, one or more liner layers are included between the dielectric layers of the interconnect layer 104 and the metallization structures 122, and/or between the dielectric layers of the interconnect layer 104 and the interconnect structures 124. The one or more liner layers may include barrier liners, adhesion liners, and/or another type of liners. Examples of materials for the one or more liners include tantalum nitride (TaN) and/or titanium nitride (TiN), among other examples.

In some implementations, the topmost layer of backend conductive structures (e.g., a topmost layer of metallization structures 122, a topmost layer of interconnect structures 124) may be coupled to connection structures at the top of the semiconductor device 100. The connection structures may include solder balls, solder bumps, contact pads (e.g., land grid array (LGA) pads), contact pins (e.g., pin grid array (PGA) pins), under bump metallization (UBM) connections, microbumps, ball grid array (BGA) balls, controlled collapse chip connection (C4) bumps, and/or other types of connection structures. In some implementations, the topmost layer of backend conductive structures (e.g., a topmost layer of metallization structures 122, a topmost layer of interconnect structures 124) may be coupled to bonding structures, such as bonding pads and/or bonding vias.

As further shown in FIG. 1, a trench capacitor structure 126 is included in the interconnect layer 104 of the semiconductor device 100. The trench capacitor structure 126 may extend through and/or may be included in one or more dielectric layers in the interconnect layer 104, such as one or more ILD layers 114 and/or one or more ESLs 116. In some implementations, an integrated circuit device 108 is electrically coupled to a trench capacitor structure 126 to form a memory cell (e.g., a dynamic random access memory (DRAM) cell or another type of capacitor-based memory cell) in the semiconductor device 100. In some implementations, a trench capacitor structure 126 is configured to provide charge decoupling for one or more integrated circuit devices 108. In some implementations, a trench capacitor structure 126 is configured to store a charge (e.g., a photocurrent) for an integrated circuit device 108 (e.g., a pixel sensor) in the semiconductor device 100 to increase the full well capacity (FWC) of pixel sensors of the semiconductor device 100. In some implementations, the trench capacitor structure 126 is configured to support global shutter functionality of the semiconductor device 100. In some implementations, the trench capacitor structure 126 is configured to provide charge smoothing for OLED display pixels of the semiconductor device 100, which enables a high brightness uniformity to be achieved for the OLED display pixels. In some implementations, a trench capacitor structure 126 is configured to perform another function in the semiconductor device 100.

The trench capacitor structure 126 may be electrically coupled and/or physically coupled to a bottom contact structure 128 at a bottom of the trench capacitor structure 126, and to a top contact structure 130 at a top of the trench capacitor structure 126. Alternatively, the trench capacitor structure 126 may be electrically coupled and/or physically coupled to a plurality of top contact structures at the top of the trench capacitor structure 126. In some implementations, the bottom contact structure 128 includes a contact structure 112 coupled to one or more integrated circuit devices 108 in the device layer 102. In some implementations, the bottom contact structure 128 and/or the top contact structure 130 may each include one or more backend conductive structures in the interconnect layer 104, such as one or more metallization structures 122 and/or one or more interconnect structures 124, among other examples.

As indicated above, FIG. 1 is provided as an example. Other examples may differ from what is described with regard to FIG. 1.

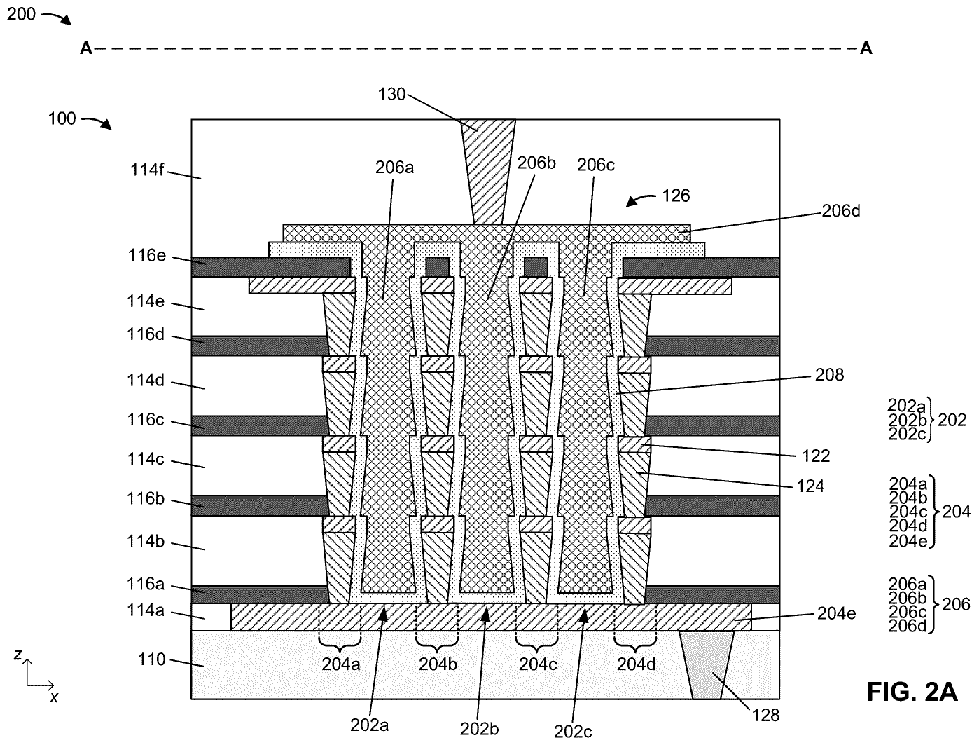

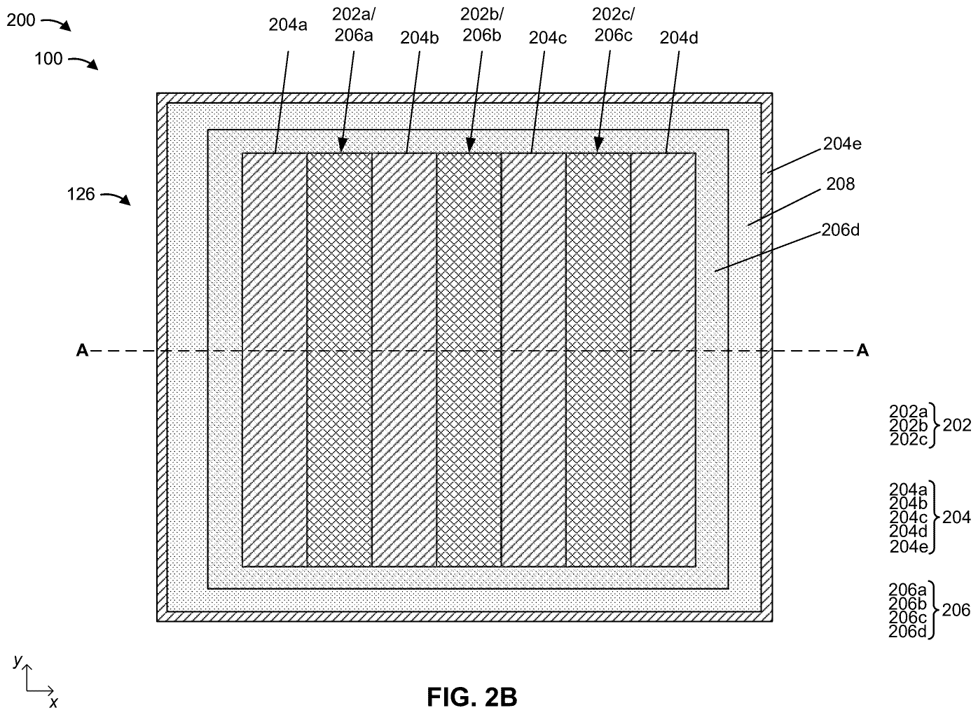

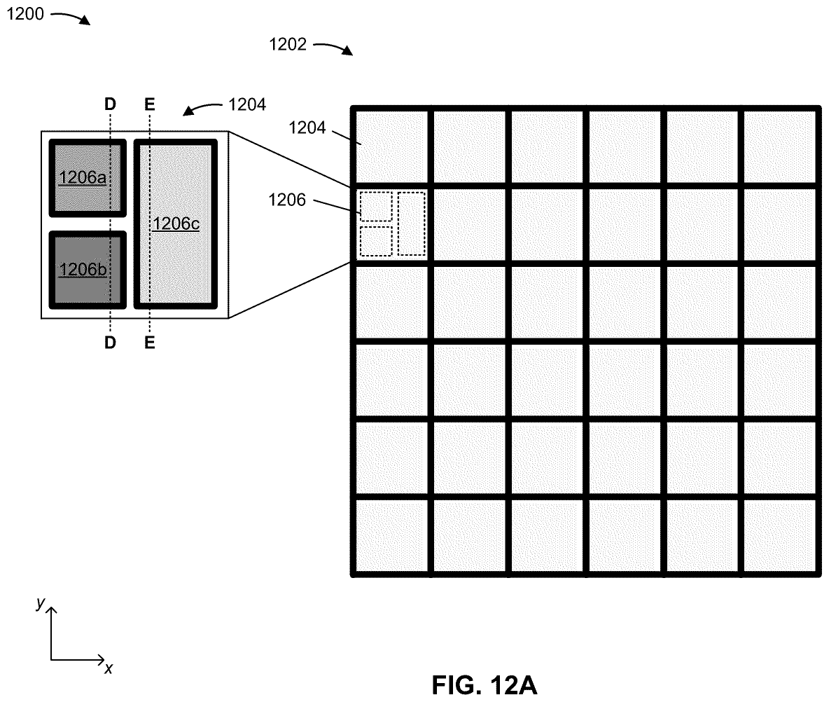

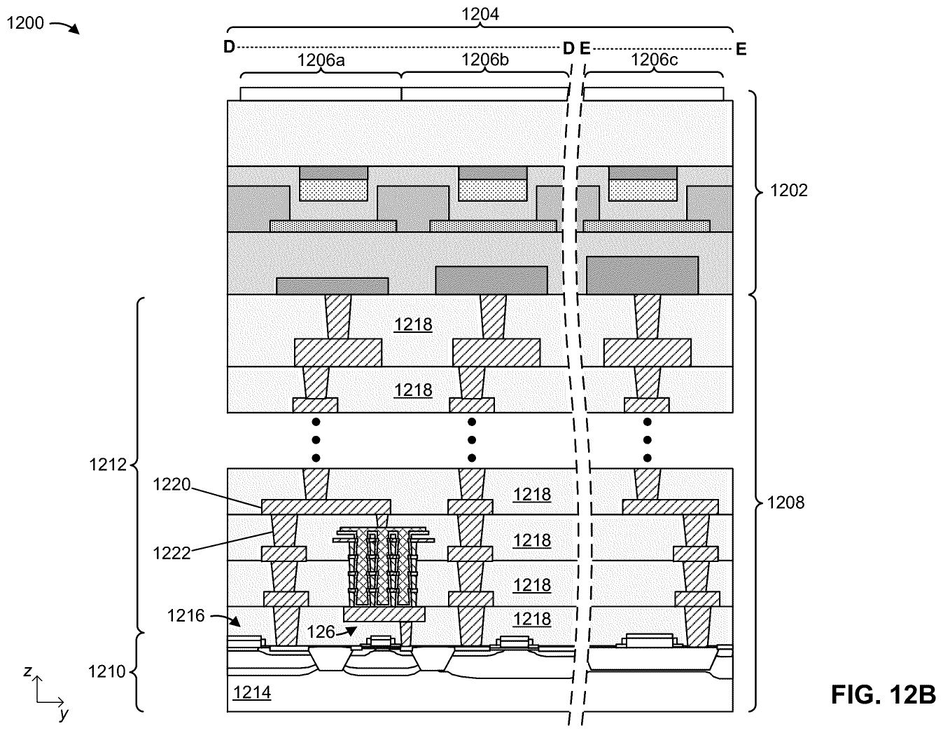

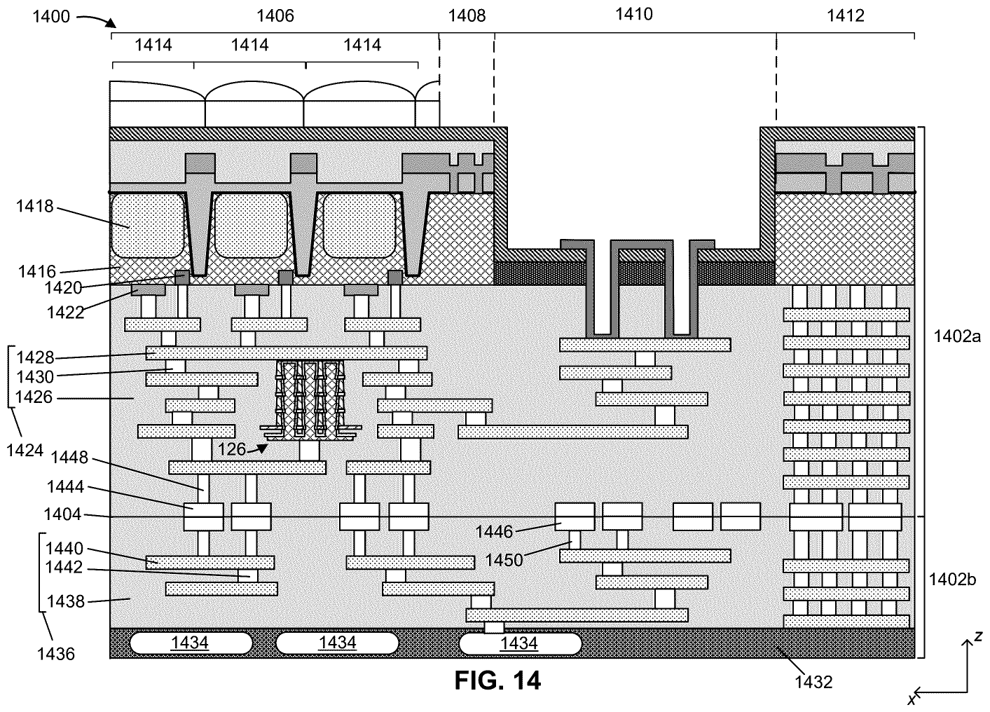

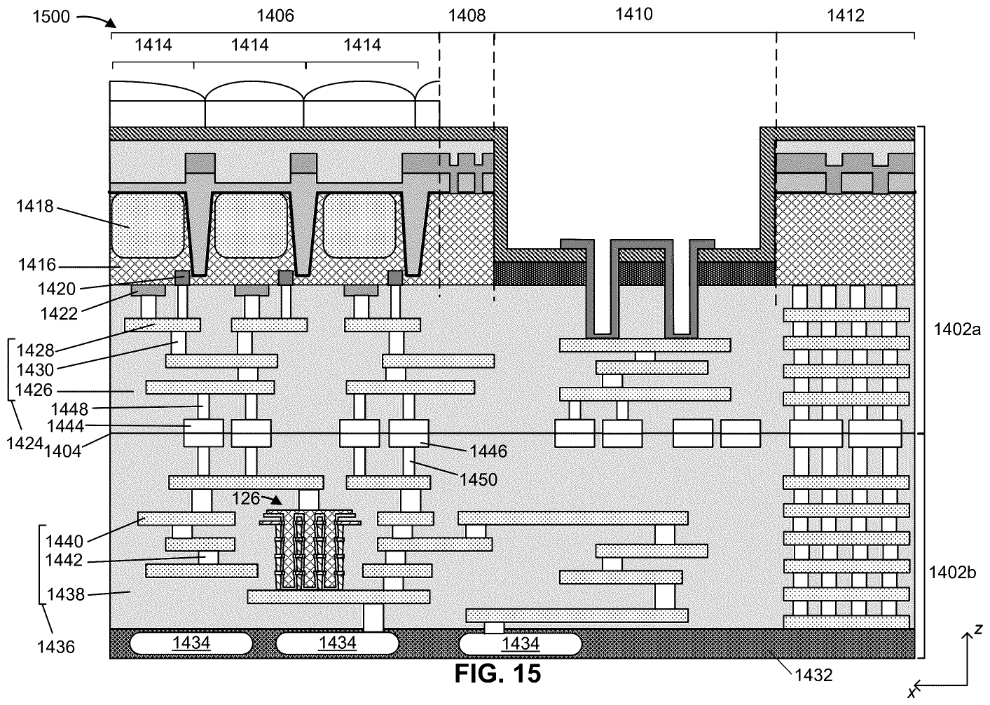

FIGS. 2A and 2B are diagrams of an example implementation 200 of a trench capacitor structure 126 described herein. The trench capacitor structure 126 illustrated and described in connection with FIGS. 2A and 2B may be included in the semiconductor device 100 (e.g., in the interconnect layer 104), and/or may be included in another semiconductor device described herein, such as the semiconductor device 1200 illustrated and described in connection with FIGS. 12A and 12B, the semiconductor device 1400 illustrated and described in connection with FIG. 14, and/or the semiconductor device 1500 illustrated and described in connection with FIG. 15, among other examples.

FIG. 2A illustrates a cross-section view of the trench capacitor structure 126. As shown in FIG. 2A, the trench capacitor structure 126 includes one or more trenches 202a-202c above the bottom contact structure 128. The bottom contact structure 128 may be included in an ILD layer 114a in the interconnect layer 104 of the semiconductor device 100. A trench 202 of the trench capacitor structure 126 may extend through one or more dielectric layers in the interconnect layer 104 of the semiconductor device 100, including through an ESL 116a, an ILD layer 114b, an ESL 116b, an ILD layer 114c, an ESL 116c, an ILD layer 114d, an ESL 116d, an ILD layer 114e, and/or an ESL 116e, among other examples. In some implementations, the trench(es) 202 may have a high aspect ratio, which is a ratio of a depth (or height) of the trench(es) 202 to a lateral width (or critical dimension) of the trench(es) 202. Thus, the trench capacitor structure 126 may be referred to as a deep trench capacitor (DTC) structure. In some implementations, the aspect ratio of a trench 202 may be approximately 10:1 or greater. In some implementations, a trench 202 may have an aspect ratio that is included in the range of approximately 20:1 to approximately 50:1. However, other values and ranges are within the scope of the present disclosure.

The sidewalls of the trenches 202a-202c are defined by vertically elongated columns 204a-204d of a bottom electrode structure 204 of the trench capacitor structure 126. The quantity of trenches 202a-202c and the quantity of columns 204a-204d illustrated in FIGS. 2A and 2B are examples, and other quantities are within the scope of the present disclosure. The columns 204a-204d extend in a z-direction (e.g., in a vertical direction) in the semiconductor device 100 and may be arranged in an x-direction (e.g., in a lateral direction) in the semiconductor device 100. In some implementations, the ratio of the lateral (x-direction) width a trench 202 (e.g., one of the trenches 202a-202c) to the lateral (x-direction) width of an elongated column (e.g., one of the columns 204a-204d) may be approximately 1:1 to approximately 2:1. However, other values and ranges are within the scope of the present disclosure.

Each column 204a-204d includes a vertical (e.g., z-direction) arrangement of backend conductive structures, including an arrangement of metallization structures 122 and interconnect structures 124. As shown in in FIG. 2A, the interconnect structures 124 included in the columns 204a-204d may have tapered sidewalls such that the lateral width of the interconnect structures 124 decreases from a top of the interconnect structures 124 toward a bottom of the interconnect structures 124.

As further shown in FIG. 2A, the bottom electrode structure 204 may further include a bottom conductive structure 204e under the columns 204a-204d. The bottom conductive structure 204e may include a horizontally elongated conductive structure that laterally spans across the columns 204a-204d. The bottom conductive structure 204e electrically connects the columns 204a-204d together in parallel, and electrically connects the columns 204a-204d to the bottom contact structure 128.

Laterally adjacent pairs of the columns 204a-204d, and the bottom conductive structure 204e, may define a trench 202 of the trenches 202a-202c. The columns 204a and 204b define the sidewalls of the trench 202a, and the bottom conductive structure 204e defines the bottom surface of the trench 202a. The columns 204b and 204c define the sidewalls of the trench 202b, and the bottom conductive structure 204e defines the bottom surface of the trench 202b. The columns 204c and 204d define the sidewalls of the trench 202c, and the bottom conductive structure 204e defines the bottom surface of the trench 202c.

As further shown in FIG. 2A, each of the columns 204a-204d may include a vertically alternating arrangement of metallization structures 122 and interconnect structures 124 in the z-direction. For example, in the column 204a, a first interconnect structure 124 may be included on the bottom conductive structure 204e, a first metallization structure 122 may be included on the first interconnect structure 124, a second interconnect structure 124 may be included on the first metallization structure 122, a third interconnect structure 124 may be included on the second interconnect structure 124, and so on. The columns 204b-204d may include a similar arrangement of metallization structures 122 and interconnect structures 124. Alternatively, one or more of the columns 204a-204d may include another arrangement of metallization structures 122 and interconnect structures 124.

As further shown in FIG. 2A, the trench capacitor structure 126 includes a top electrode structure 206 and an insulator layer 208 between the bottom electrode structure 204 and the top electrode structure 206. The bottom electrode structure 204, the insulator layer 208, and the top electrode structure 206 correspond to an MIM structure of the trench capacitor structure 126. Thus, the trench capacitor structure 126 may also be referred to as an MIM capacitor structure. The insulator layer 208 may be included in, and may conform to the profile of, the trenches 202a-202c such that the insulator layer 208 conforms to the sidewalls of the columns 204a-204d and the top surface of the bottom conductive structure 204e.

The top electrode structure 206 also includes a plurality of columns 206a-206c (e.g., vertically elongated columns or “fingers”) that extend into the trenches 202a-202c. Thus, the columns 206a-206c of the top electrode structure 206 are interspersed between the columns 204a-204d of the bottom electrode structure 204. The columns 206a-206c of the top electrode structure 206 may extend in the z-direction between the top of the columns 204a-204d of the bottom electrode structure 204 and the bottom of the columns 204a-204d of the bottom electrode structure 204. The bottoms of the columns 206a-206c of the top electrode structure 206 may be included on the top of the bottom conductive structure 204e of the bottom electrode structure 204.

The top electrode structure 206 may further include a top conductive structure 206d above the columns 206a-206c. The top conductive structure 206d may include a horizontally elongated conductive structure that laterally spans across the columns 206a-206c. The top conductive structure 206d is merged section of the top electrode structure 206 that electrically connects the columns 206a-206c together in parallel, and that electrically connects the columns 206a-206c to the top contact structure 130.

The bottom electrode structure 204 (also referred to as a capacitor bottom metal (CBM)) and the top electrode structure 206 (also referred to as a capacitor top metal (CTM)) may each include one or more electrically conductive metals, one or more electrically conductive metal-containing materials, one or more electrically conductive ceramic materials, and/or other types of electrically conductive materials. Examples include tungsten (W), cobalt (Co), ruthenium (Ru), titanium (Ti), aluminum (Al), copper (Cu), gold (Au), titanium nitride (TiN), and/or tantalum nitride (TaN), among other examples. In some implementations, the bottom electrode structure 204 and the top electrode structure 206 include the same material or the same material composition. In some implementations, the bottom electrode structure 204 and the top electrode structure 206 include different materials or different material compositions.

The insulator layer 208 may include one or more electrically insulating materials. In some implementations, the insulator layer 208 includes one or more low-k dielectric materials such as silicon oxide (SiOₓ such as SiO₂). Additionally and/or alternatively, the insulator layer 208 may include one or more high-k dielectric materials such as silicon oxynitride (SiON), zirconium oxide (ZrOₓ such as ZrO₂), aluminum oxide (AlₓO_{y} such as Al₂O₃), silicon nitride (SiₓN_{y} such as Si₃N₄), yttrium oxide (YₓO_{y} such as Y₂O₃), lanthanum oxide (LaₓO_{y} such as La₂O₃), hafnium oxide (HfOₓ such as HfO₂), and/or one or more doped high-k dielectric materials, among other examples.

In some implementations, a thickness of the insulator layer 208 may be included in a range of approximately 1 nanometer to approximately 1 micron. However, other values for the range are within the scope of the present disclosure. In some implementations, the ratio of the lateral (x-direction) width a trench 202 (e.g., one of the trenches 202a-202c) to the thickness of the insulator layer 208 may be included in a range of approximately 5:1 to approximately 10:1. In some implementations, the ratio of the lateral (x-direction) width of an elongated column 204 (e.g., one of the columns 204a-204d) to the thickness of the insulator layer 208 may be included in a range of approximately 5:1 to approximately 10:1. However, other values and ranges are within the scope of the present disclosure.

FIG. 2B illustrates a top view of the trench capacitor structure 126 in which the location of the cross-section view of FIG. 2A along the line A-A is indicated. As shown in FIG. 2B, the trenches 202a-202c (and the columns 206a-206c of the top electrode structure 206 respectively included in the trenches 202a-202c) may extend in a y-direction in the semiconductor device 100 and may be arranged in the x-direction in the semiconductor device 100. Similarly, the columns 204a-204d of the bottom electrode structure 204 may extend in a y-direction in the semiconductor device 100 and may be arranged in the x-direction in the semiconductor device 100. The trenches 202a-202c (and the columns 206a-206c of the top electrode structure 206 respectively included in the trenches 202a-202c) and the columns 204a-204d of the bottom electrode structure 204 may be arranged in an alternating manner in the x-direction in the semiconductor device 100.

The bottom conductive structure 204e of the bottom electrode structure 204 may laterally extend outward past the columns 204a-204d in the x-direction and/or in the y-direction. Similarly, top conductive structure 206d of the top electrode structure 206 may laterally extend outward past the columns 206a-206c in the x-direction and/or in the y-direction. In some implementations, the bottom conductive structure 204e may laterally extend (e.g., in the x-direction) outward past the ends of the top conductive structure 206d. In some implementations, the ends of the bottom conductive structure 204e and the ends of the top conductive structure 206d may be substantially vertically aligned. In some implementations, the top conductive structure 206d may laterally extend (e.g., in the x-direction) outward past the ends of the bottom conductive structure 204e.

As indicated above, FIGS. 2A and 2B are provided as an example. Other examples may differ from what is described with regard to FIGS. 2A and 2B.

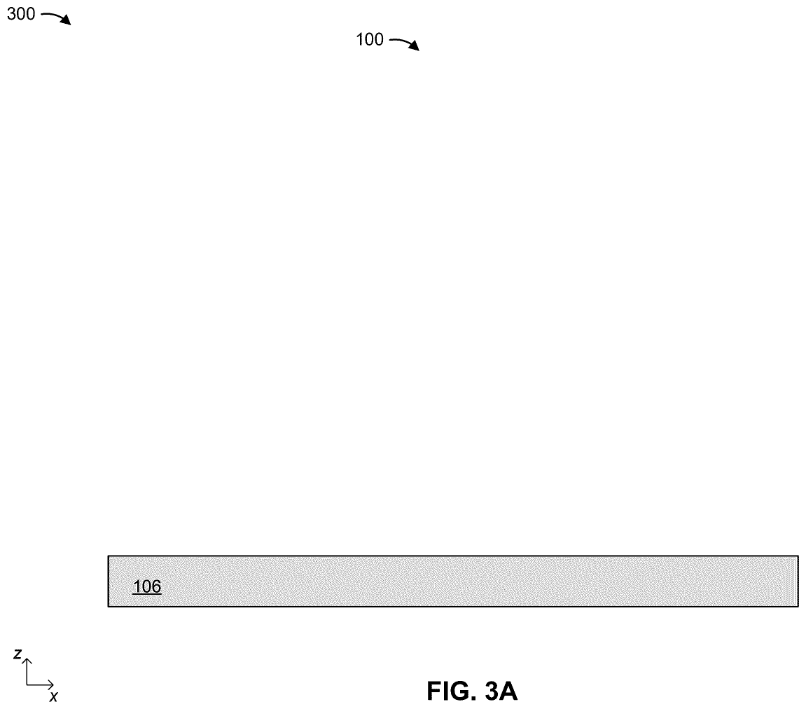

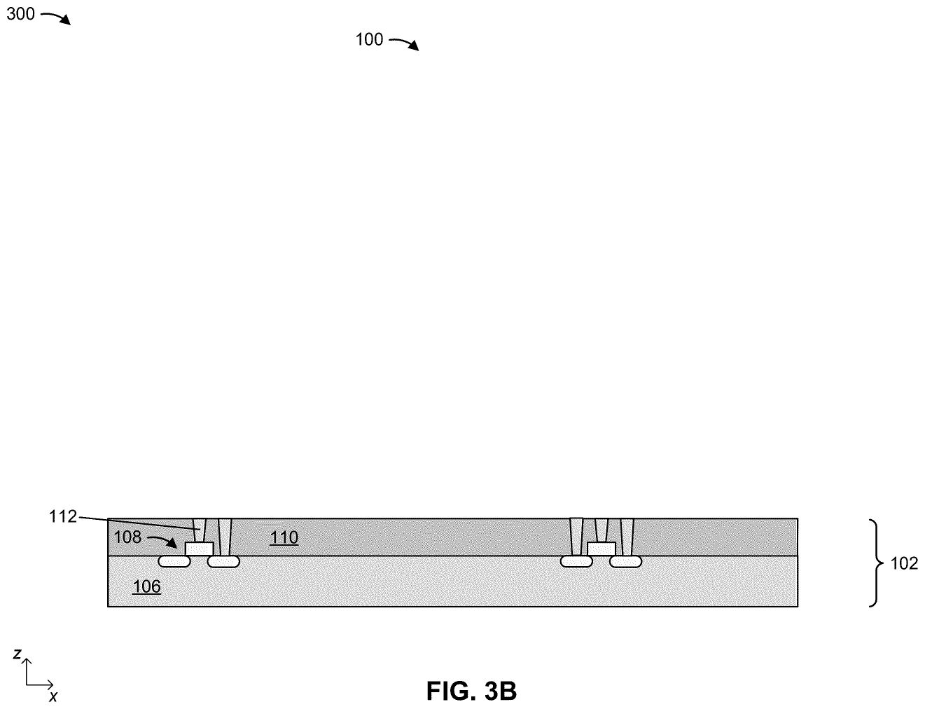

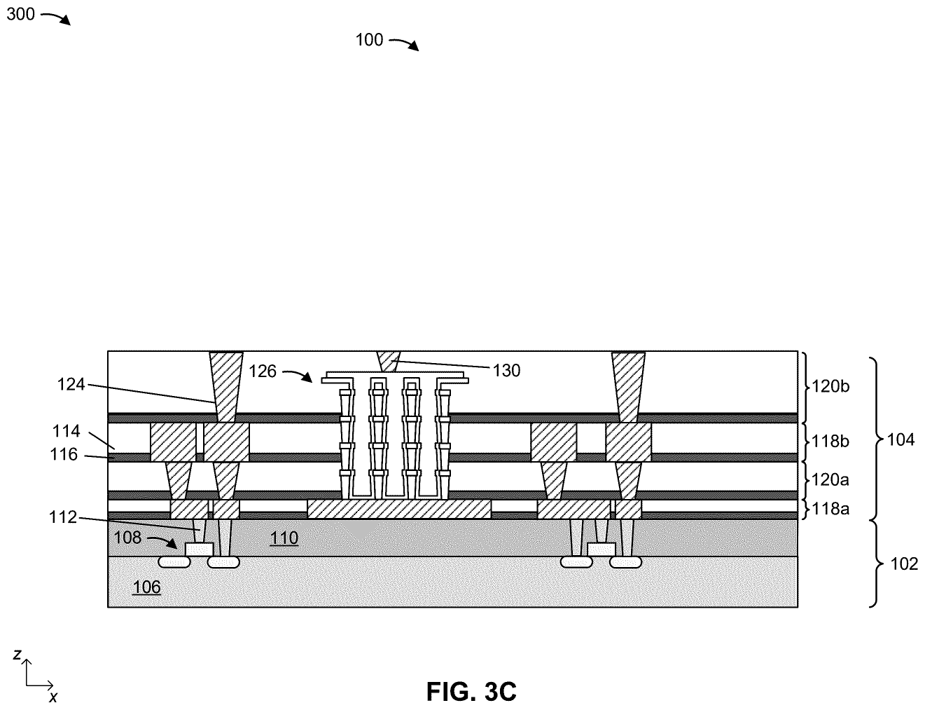

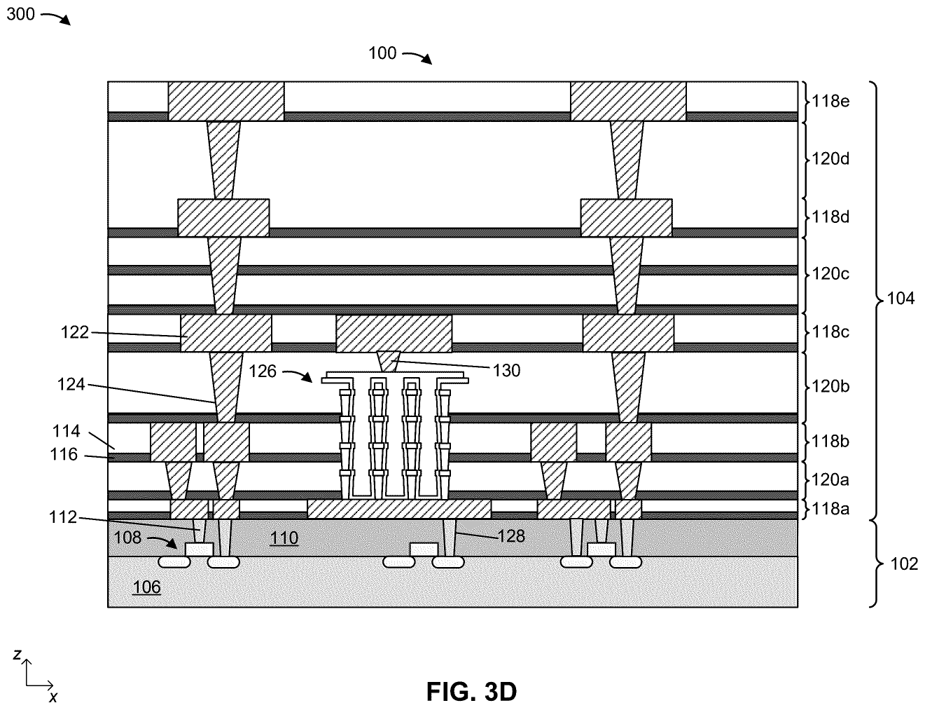

FIGS. 3A-3D are diagrams of an example implementation 300 of forming the semiconductor device 100 described herein. Additionally and/or alternatively, the techniques and/or operations described in connection with one or more of FIGS. 3A-3D may be used to form another semiconductor device described herein, such as the semiconductor device 1200 illustrated and described in connection with FIGS. 12A and 12B, the semiconductor device 1400 illustrated and described in connection with FIG. 14, and/or the semiconductor device 1500 illustrated and described in connection with FIG. 15, among other examples. In some implementations, one or more of the semiconductor processing operations described in connection with FIGS. 3A-3D may be performed using one or more semiconductor processing tools, such as a deposition tool, an exposure tool, a developer tool, an etch tool, a planarization tool, an ion implantation tool, a wafer/die transport tool, and/or another type of semiconductor processing tool.

As shown in FIG. 3A, the substrate 106 is provided. The substrate 106 may be provided in the form of a semiconductor wafer such as a silicon (Si) wafer, an SOI wafer, and/or another type of semiconductor work piece. The semiconductor device 100 may be formed on the semiconductor wafer with other semiconductor devices.

As shown in FIG. 3B, the integrated circuit devices 108 may be formed in and/or on the substrate 106 in the device layer 102 of the semiconductor device 100. One or more semiconductor processing tools may be used to form one or more portions of the integrated circuit devices 108. For example, an ion implantation tool may be used to dope one or more regions in the substrate 106 with one or more types of dopants to form well regions, implant regions, and/or other types of doped regions in the substrate 106 for the integrated circuit devices 108. As another example, a deposition tool may be used to perform various deposition operations to deposit layers and/or structures of the integrated circuit devices 108, and/or to deposit photoresist layers for etching the substrate 106 and/or portions of the deposited layers. As another example, an exposure tool may be used to expose the photoresist layers to form patterns in the photoresist layers. As another example, a developer tool may develop the patterns in the photoresist layers. As another example, an etch tool may be used to etch the substrate 106 and/or portions of the deposited layers to form the integrated circuit devices 108. As another example, a planarization tool may be used to planarize portions of the integrated circuit devices 108. As another example, a plating tool may be used to deposit metal structures and/or layers of the integrated circuit devices 108.

As further in FIG. 3B, a deposition tool is used to deposit the dielectric layer 110 over and/or on the substrate 106 and over and/or on the integrated circuit devices 108. A deposition tool may be used to deposit the dielectric layer 110 using a physical vapor deposition (PVD) technique, an atomic layer deposition (ALD) technique, a chemical vapor deposition (CVD) technique, an oxidation technique, and/or another suitable deposition technique. In some implementations, a planarization tool may be used to perform a planarization operation such as a chemical mechanical planarization (CMP) operation to planarize the dielectric layer 110 after the dielectric layer 110 is deposited.

As further shown in FIG. 3B, the contact structures 112 of the integrated circuit devices 108 may be formed through the dielectric layer 110. The contact structures 112 may be formed in recesses in the dielectric layer 110. In some implementations, a pattern in a photoresist layer is used to etch the dielectric layer 110 to form the recesses. In these implementations, a deposition tool may be used to form the photoresist layer on the dielectric layer 110. An exposure tool may be used to expose the photoresist layer to a radiation source to pattern the photoresist layer. A developer tool may be used to develop and remove portions of the photoresist layer to expose the pattern. An etch tool may be used to etch the dielectric layer based on the pattern to form the recesses. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the dielectric layer 110 based on a pattern to form the recesses.

The contact structures 112 may be formed in the recesses. In some implementations, a contact structure 112 (e.g., a gate contact) is formed on a gate structure of an integrated circuit device 108. In some implementations, a contact structure 112 (e.g., a source/drain contact) is formed on a source/drain region of an integrated circuit device 108. A deposition tool may be used to deposit the material of the contact structures 112 in the recesses using a CVD technique, a PVD technique, an ALD technique, an electroplating technique, and/or another suitable deposition technique. The material of the contact structures 112 may be deposited in one or more deposition operations. In some implementations, a seed layer is first deposited, and the material of the contact structures 112 is deposited on the seed layer. In some implementations, a planarization tool is used to perform a planarization operation (e.g., a CMP operation) to planarize the contact structures 112 after the contact structures 112 are deposited such that the tops of the contact structures 112 are approximately co-planar with the top of the dielectric layer 110.

As shown in FIG. 3C, a first portion of the interconnect layer 104 of the semiconductor device 100 is formed above the dielectric layer 110. One or more deposition tools are used to deposit alternating layers of ILD layers 114 and ESLs 116 in the first portion of the interconnect layer 104 of the semiconductor device 100. In this way, the ILD layers 114 and ESLs 116 may be arranged in the z-direction in the semiconductor device 100. One or more deposition tools may be used to deposit each of the ILD layers 114 and each of the ESLs 116 using a PVD technique, an ALD technique, a CVD technique, an oxidation technique, and/or another suitable deposition technique. In some implementations, a planarization tool may be used to planarize the ILD layers 114 and/or the ESLs 116 after the ILD layers 114 and/or the ESLs 116 are deposited.

As further shown in FIG. 3C, a deposition tool, an exposure tool, a developer tool, an etch tool, a planarization tool, a plating tool, and/or another semiconductor processing tool may be used to perform various operations to form the metallization structures 122 and to form the interconnect structures 124 in the first portion of the interconnect layer 104 of the semiconductor device 100. The bottom contact structure 128 of the trench capacitor structure 126 may also be formed in the first portion of the interconnect layer 104.

In some implementations, the first portion of the interconnect layer 104 may be formed in a plurality of layers. For example, an ILD layer 114 and an ESL 116 may be formed (e.g., using one or more deposition tools and/or one or more planarization tools), recesses may be formed in and/or through the ILD layer 114 and the ESL 116 (e.g., using an exposure tool, a developer tool, and/or an etch tool), and the layer 118a (e.g., the M0 layer) of metallization structures 122 may be formed in the ILD layer 114 and the ESL 116 (e.g., using one or more deposition tools and/or one or more planarization tools). Another ILD layer 114 and another ESL 116 may be formed, and the layer 120a (e.g., the VO layer) of interconnect structures 124 may be formed in the ILD layer 114 and the ESL 116. The layers 118b, 118c, 120b, and 120c may be formed in a similar manner.

One or more deposition tools may be used to deposit the metallization structures 122, the interconnect structures 124, and/or the bottom contact structure 128 using a PVD technique, an ALD technique, a CVD technique, an electroplating technique (e.g., an electro-chemical plating technique), and/or another suitable deposition technique. In some implementations, a planarization tool may be used to planarize the metallization structures 122, the interconnect structures 124, and/or the bottom contact structure 128 after the metallization structures 122, the interconnect structures 124, and/or the bottom contact structure 128 are deposited.

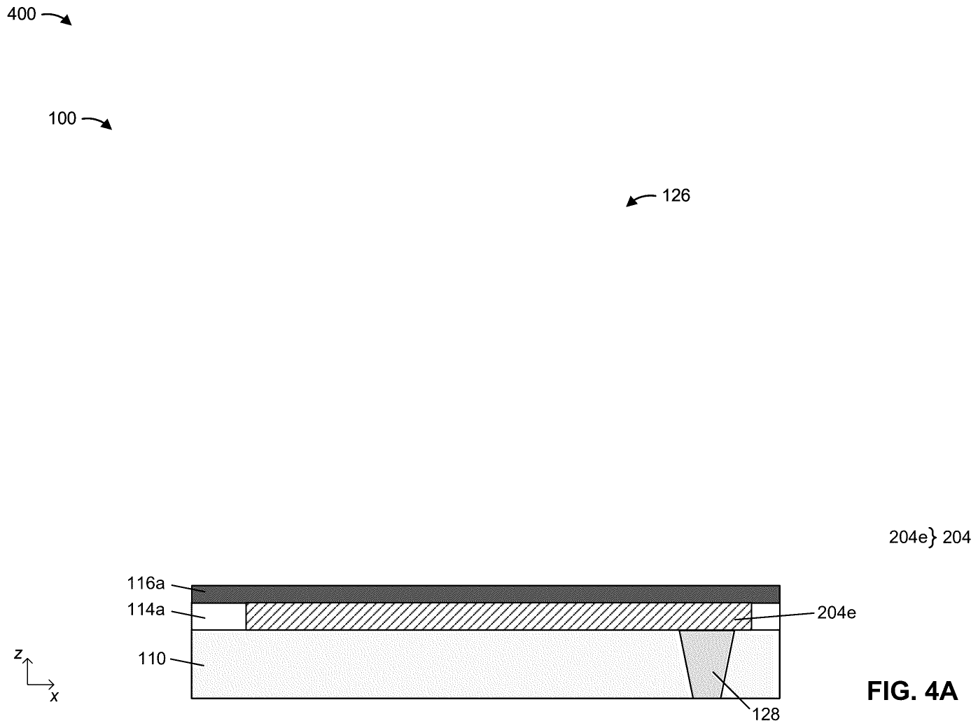

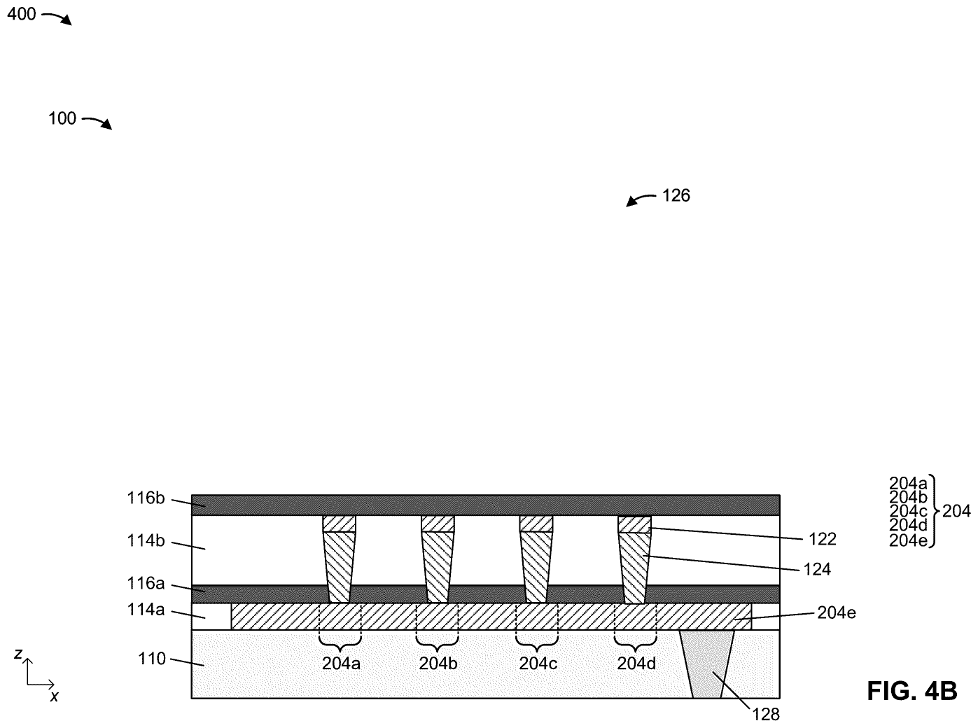

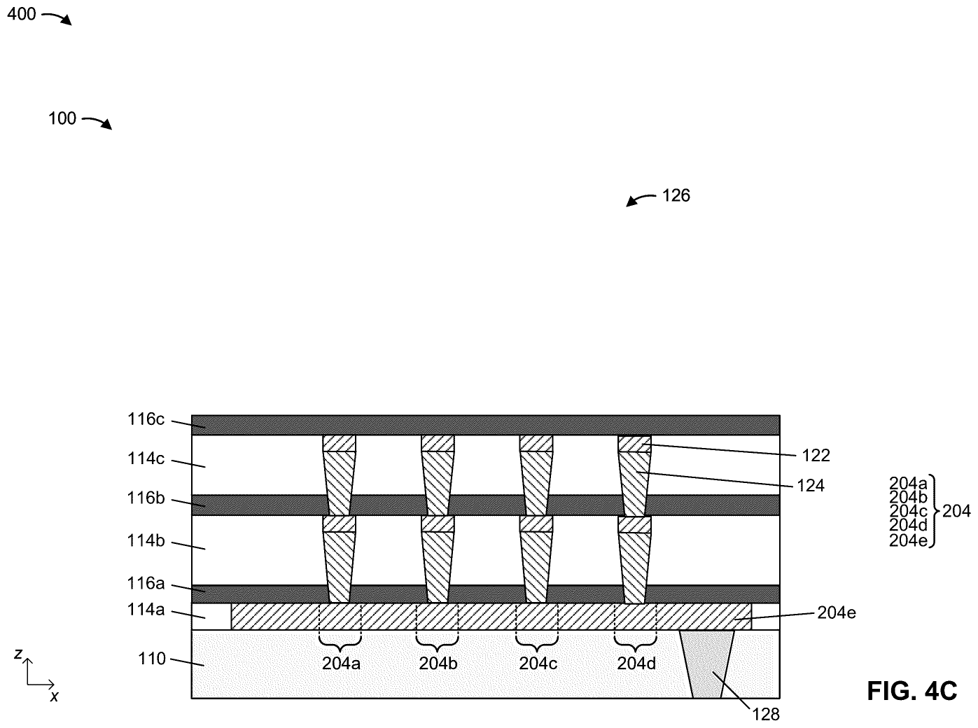

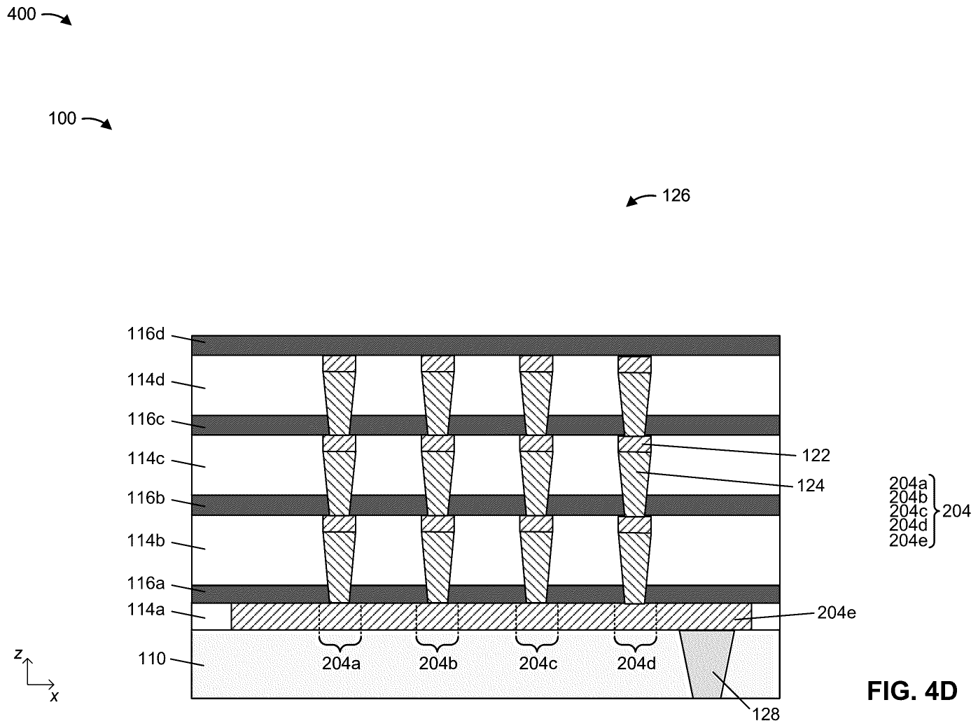

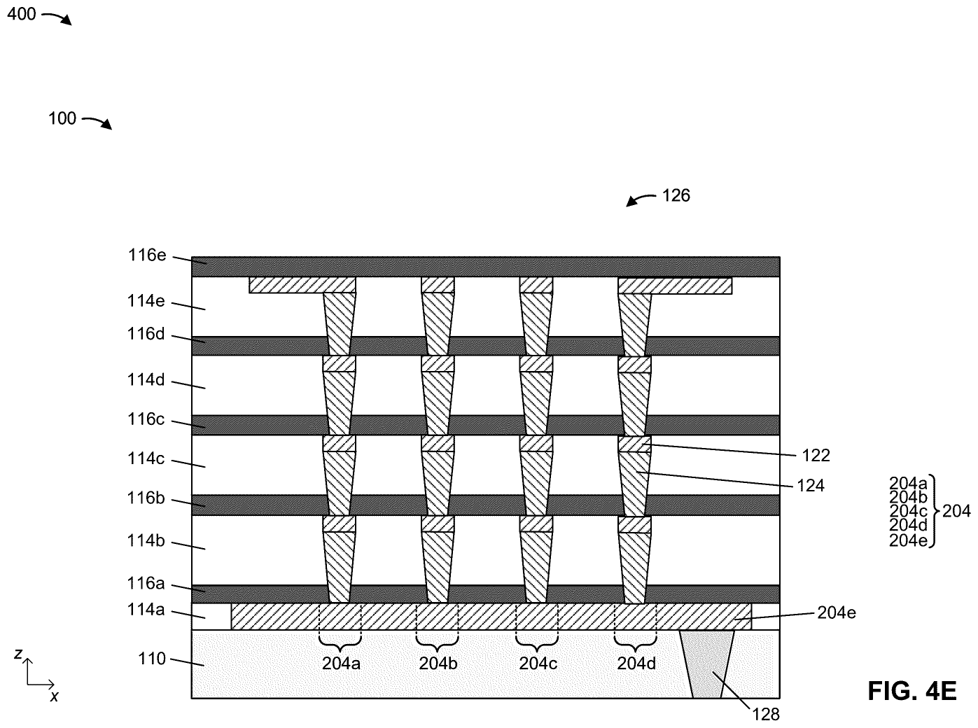

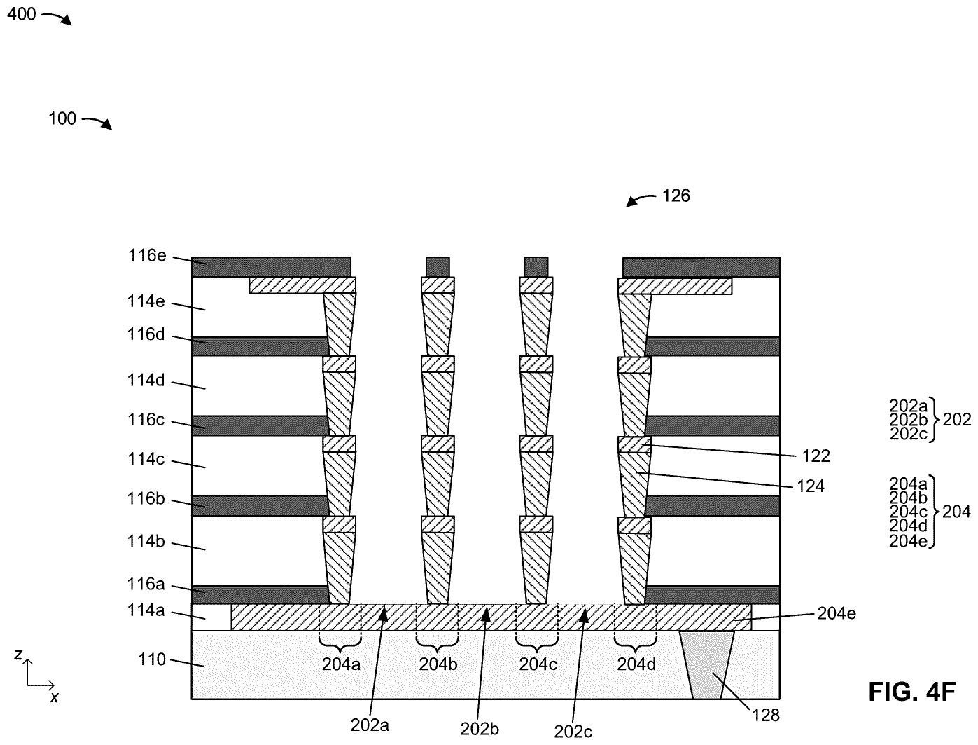

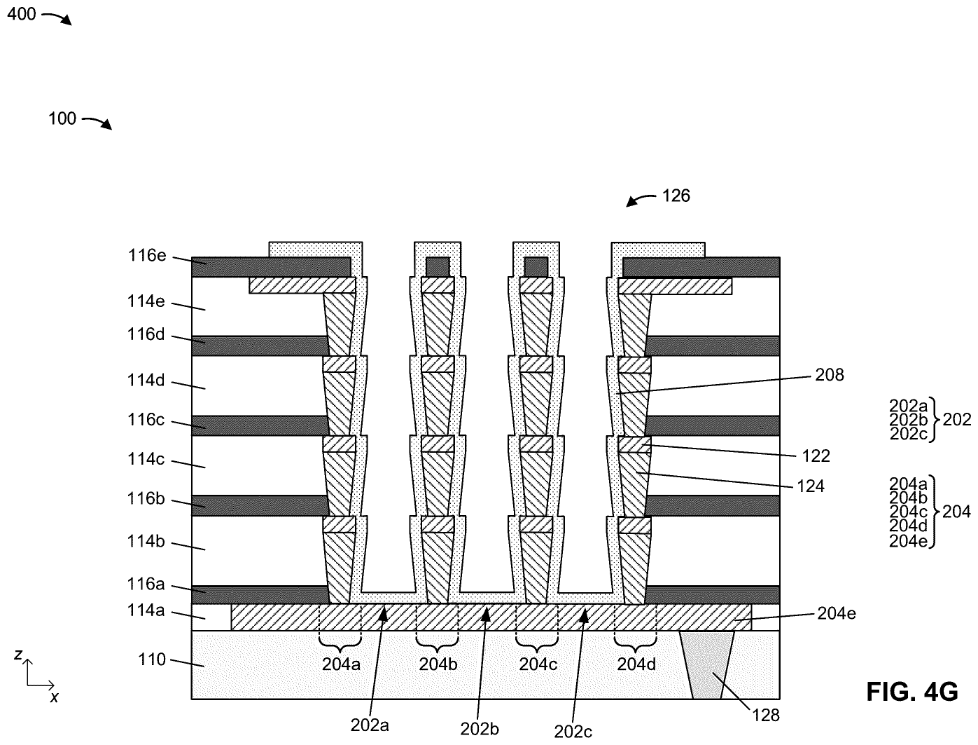

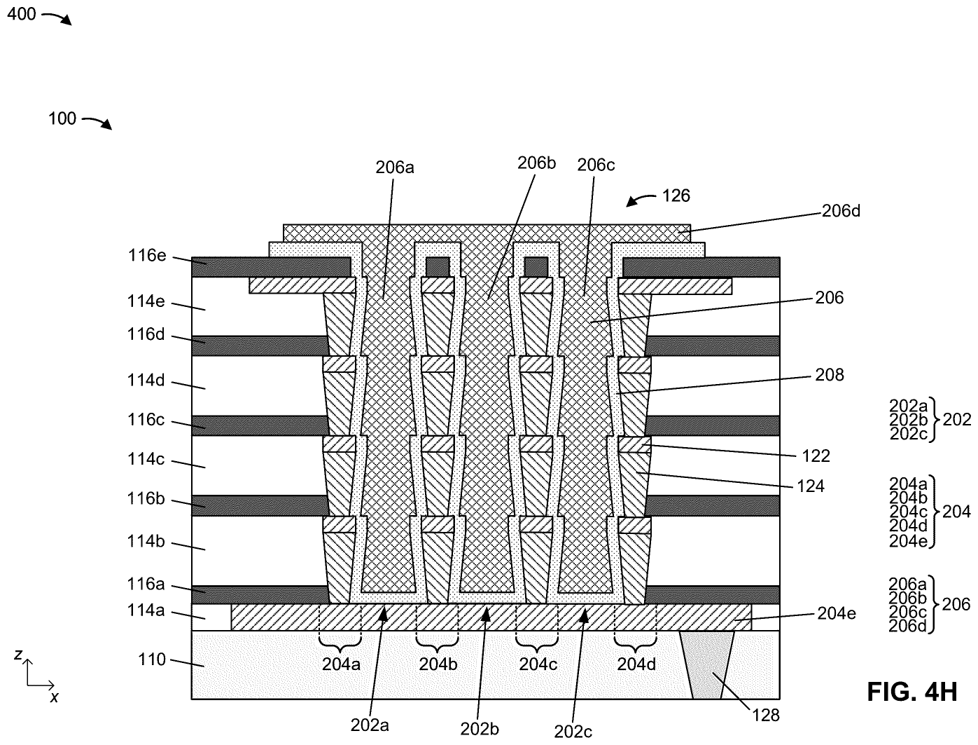

As further shown in FIG. 3C, a trench capacitor structure 126 may be formed in one or more dielectric layers in the interconnect layer 104. The trench capacitor structure 126 may be formed such that the columns 204a-204d and the bottom conductive structure 204e of the bottom electrode structure 204 of the trench capacitor structure 126 are formed in the same set of operations as the metallization structures 122 and the interconnect structures 124 in the layers 118a, 120a, 118b, and/or 120b, among other examples. The portions of the ILD layers 114 and the ESLs 116 between the columns 204a-204d are removed to form the trenches 202a-202c, and the insulator layer 208 and the top electrode structure 206 are formed in the trenches 202a-202c. The top contact structure 130 may be formed on the top electrode structure 206. An example process for forming the trench capacitor structure 126 is illustrated and described in connection with FIGS. 4A-4I.

As shown in FIG. 3D, a second portion of the interconnect layer 104 of the semiconductor device 100 is formed above the first portion of the interconnect layer 104, including above the trench capacitor structure 126. The second portion of the interconnect layer 104 may be formed in a similar manner as the first portion of the interconnect layer 104 as described in connection with FIG. 3C.

As indicated above, FIGS. 3A-3D are provided as an example. Other examples may differ from what is described with regard to FIGS. 3A-3D.

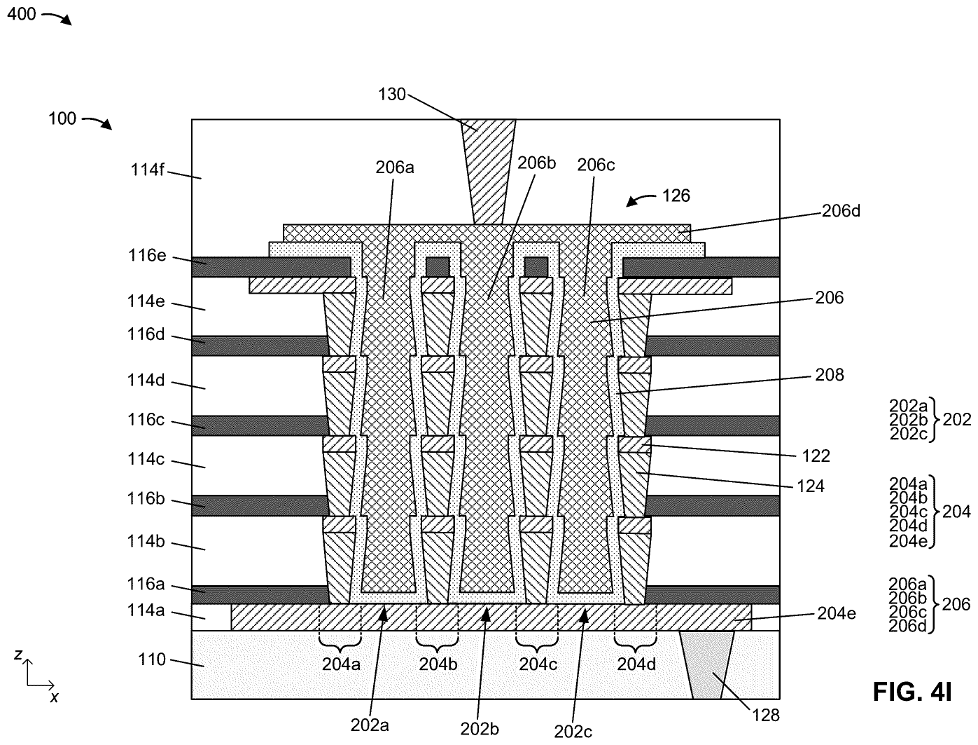

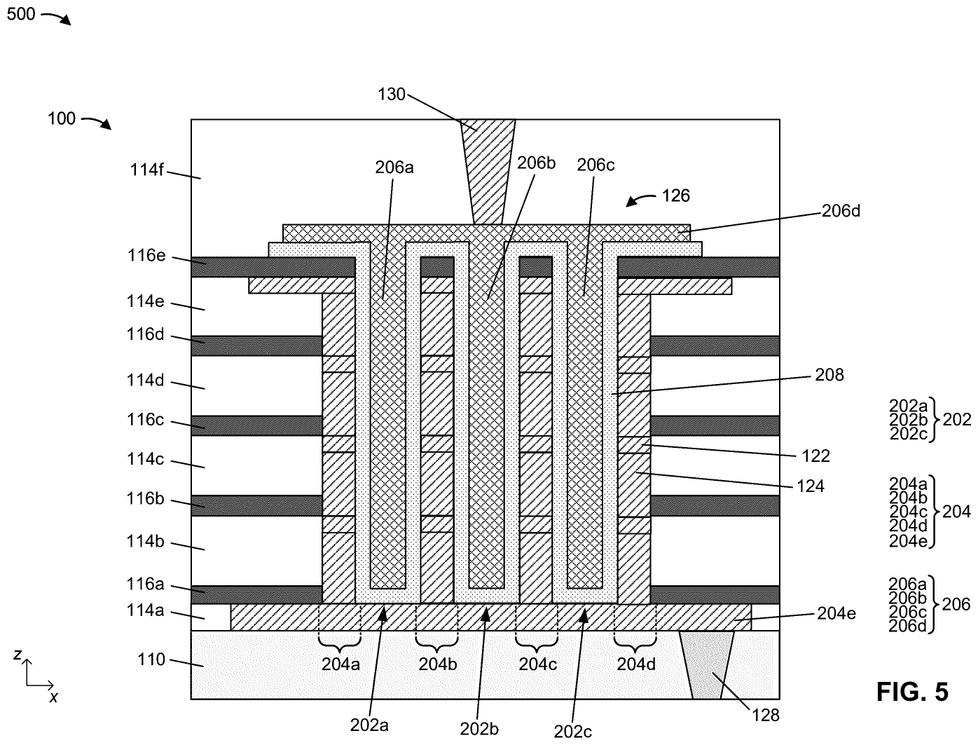

FIGS. 4A-4I are diagrams of an example implementation 400 of forming a trench capacitor structure 126 described herein. While FIGS. 4A-4I illustrate an example of forming the example implementation 200 of the trench capacitor structure 126 illustrated in FIGS. 2A and 2B, the techniques and operations described in connection with FIGS. 4A-4I may be performed to form other implementations of trench capacitor structures 126 described herein, including in connection with FIGS. 5, 6, 7, 8, 10 and/or 11A-11C, among other examples.

In some implementations, one or more of the semiconductor processing operations described in connection with FIGS. 4A-4I may be performed using one or more semiconductor processing tools, such as a deposition tool, an exposure tool, a developer tool, an etch tool, a planarization tool, a wafer/die transport tool, and/or another type of semiconductor processing tool. In some implementations, one or more of the semiconductor processing operations described in connection with FIGS. 4A-4I may be performed as part of the process for forming the semiconductor device 100 described in connection with FIGS. 3A-3D.

As shown in FIG. 4A, the bottom contact structure 128 of the trench capacitor structure 126 may be formed in the dielectric layer 110. The bottom conductive structure 204e of the bottom electrode structure 204 may be formed in the ILD layer 114a and may land on the bottom contact structure 128. The ESL 116a may be formed over and/or on the ILD layer 114a and the bottom conductive structure 204e.

To form the bottom contact structure 128, a recess may be formed in the dielectric layer 110, and the bottom contact structure 128 may be deposited in the recess. In some implementations, a pattern in a photoresist layer is used to etch the dielectric layer 110 to form the recess. In these implementations, a deposition tool may be used to form the photoresist layer on the dielectric layer 110 (e.g., using a spin-coating technique and/or another suitable deposition technique). An exposure tool may be used to expose the photoresist layer to a radiation source to pattern the photoresist layer. A developer tool may be used to develop and remove portions of the photoresist layer to expose the pattern. An etch tool may be used to etch the dielectric layer 110 based on the pattern to form the recess. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the dielectric layer 110 based on a pattern.

A deposition tool may be used to deposit the material of the bottom contact structure 128 using a CVD technique, a PVD technique, an ALD technique, an electroplating technique, and/or another suitable deposition technique. The bottom contact structure 128 may be deposited in one or more deposition operations. In some implementations, a seed layer is first deposited, and the bottom contact structure 128 is deposited on the seed layer. In some implementations, a liner (e.g., a barrier liner, an adhesion liner) is first deposited, and the bottom contact structure 128 is deposited on the liner. In some implementations, the bottom contact structure 128 is deposited on a metal silicide layer, such as a titanium silicide (TiSi) layer and/or a ruthenium silicide (RuSi) layer, among other examples of metal silicide materials. In some implementations, a planarization tool is used to perform a planarization operation (e.g., a CMP operation) to planarize the bottom contact structure 128 after the bottom contact structure 128 is deposited.

The ILD layer 114a may then be deposited. A deposition tool may be used to deposit the ILD layer 114a using a PVD technique, an ALD technique, a CVD technique, an oxidation technique, and/or another suitable deposition technique. The ILD layer 114a may be deposited in one or more deposition operations. In some implementations, a planarization tool may be used to perform a planarization operation (e.g., a CMP operation) to planarize the ILD layer 114a after the ILD layer 114a is deposited.

To form the bottom conductive structure 204e of the bottom electrode structure 204, a recess may be formed in the ILD layer 114a, and the bottom conductive structure 204e may be deposited in the recess. The recess may be formed such that the top of the bottom contact structure 128 is exposed in the recess. This enables a portion of the bottom conductive structure 204e to land on the bottom contact structure 128 such that the bottom contact structure 128 and the bottom conductive structure 204e are electrically connected.

In some implementations, a pattern in a photoresist layer is used to etch the ILD layer 114a to form the recess. In these implementations, a deposition tool may be used to form the photoresist layer on the ILD layer 114a (e.g., using a spin-coating technique and/or another suitable deposition technique). An exposure tool may be used to expose the photoresist layer to a radiation source to pattern the photoresist layer. A developer tool may be used to develop and remove portions of the photoresist layer to expose the pattern. An etch tool may be used to etch the ILD layer 114a based on the pattern to form the recess. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the ILD layer 114a based on a pattern.

A deposition tool may be used to deposit the material of the bottom conductive structure 204e using a CVD technique, a PVD technique, an ALD technique, an electroplating technique, and/or another suitable deposition technique. The bottom conductive structure 204e may be deposited in one or more deposition operations. In some implementations, a seed layer is first deposited, and the bottom conductive structure 204e is deposited on the seed layer. In some implementations, a liner (e.g., a barrier liner, an adhesion liner) is first deposited, and the bottom conductive structure 204e is deposited on the liner. In some implementations, a planarization tool is used to perform a planarization operation (e.g., a CMP operation) to planarize the bottom conductive structure 204e after the bottom conductive structure 204e is deposited.

The ESL 116a may then be deposited. A deposition tool may be used to deposit the ESL 116a using a PVD technique, an ALD technique, a CVD technique, an oxidation technique, and/or another suitable deposition technique. The ESL 116a may be deposited in one or more deposition operations. In some implementations, a planarization tool may be used to perform a planarization operation (e.g., a CMP operation) to planarize the ESL 116a after the ESL 116a is deposited.

As shown in FIG. 4B, the ILD layer 114b may be formed on the ESL 116a. The first row of interconnect structures 124 of the columns 204a-204d of the bottom electrode structure 204 may be formed in the ILD layer 114b such that the first row of interconnect structures 124 lands on the bottom conductive structure 204e of the bottom electrode structure 204. The first row of metallization structures 122 of the columns 204a-204d of the bottom electrode structure 204 may be formed in the ILD layer 114b such that the first row of metallization structures 122 lands on the first row of interconnect structures 124. The ESL 116b may be formed on the ILD layer 114b and on the first row of metallization structures 122.

A deposition tool may be used to deposit the ILD layer 114b using a PVD technique, an ALD technique, a CVD technique, an oxidation technique, and/or another suitable deposition technique. The ILD layer 114b may be deposited in one or more deposition operations. In some implementations, a planarization tool may be used to perform a planarization operation (e.g., a CMP operation) to planarize the ILD layer 114b after the ILD layer 114b is deposited.

In some implementations, the first row of interconnect structures 124 is formed first, and the first row of metallization structures 122 is formed after formation of the first row of interconnect structures 124. For example, a first portion of the ILD layer 114b may be formed, recesses for the first row of interconnect structures 124 may be formed in and/or through the first portion of the ILD layer 114b and the ESL 116a such that the top surface of the bottom conductive structure 204e is exposed through the recesses, and the first row of interconnect structures 124 may then be formed in the recesses. Subsequently, a second portion of the ILD layer 114b may be formed, recesses for the first row of metallization structures 122 may be formed in and/or through the second portion of the ILD layer 114b such that the tops of the first row of interconnect structures 124 are exposed through the recesses, and the first row of metallization structures 122 may then be formed in the recesses on the first row of interconnect structures 124.

Alternatively, the recesses for the first row of metallization structures 122 and the recesses for the first row of interconnect structures 124 may be formed as a dual damascene recesses. For example, the recess for the first interconnect structure 124 of the column 204a may correspond to a via portion of a dual damascene recess, and the recess for the first metallization structure 122 of the column 204a may correspond to a trench portion of the dual damascene recess. The dual damascene recesses for the columns 204b-204d may be formed in a similar manner. The dual damascene recesses may be formed using a via-first technique in which the vias of the dual damascene recesses corresponding to the recesses for the first row of interconnect structures 124 are formed first, followed by the trenches of the dual damascene recesses corresponding to the recesses for the first row of metallization structures 122. Alternatively, the dual damascene recesses may be formed using or a trench-first technique in which the trenches of the dual damascene recesses corresponding to the recesses for the first row of metallization structures 122 are formed first, followed by the vias of the dual damascene recesses corresponding to the recesses for the first row of interconnect structures 124. The first row of interconnect structures 124 and the first row of metallization structures 122 may be deposited together in the dual damascene recesses.

The ESL 116b may then be deposited. A deposition tool may be used to deposit the ESL 116b using a PVD technique, an ALD technique, a CVD technique, an oxidation technique, and/or another suitable deposition technique. The ESL 116b may be deposited in one or more deposition operations. In some implementations, a planarization tool may be used to perform a planarization operation (e.g., a CMP operation) to planarize the ESL 116b after the ESL 116b is deposited.

As shown in FIGS. 4C-4E, additional rows of metallization structures 122 and additional rows of interconnect structures 124 of the columns 204a-204d of the bottom electrode structure 204 may be formed in a similar manner as described in connection with FIG. 4B. The rows of metallization structures 122 and the rows of interconnect structures 124 may be stacked and arranged in the z-direction to form the columns 204a-204d of the bottom electrode structure 204.

The rows of metallization structures 122 and the rows of interconnect structures 124 of the columns 204a-204d are laterally spaced apart in the x-direction such that the columns 204a-204d of the bottom electrode structure 204 define spaces between the columns 204a-204d of the bottom electrode structure 204.

As shown in FIG. 4F, the spaces between the columns 204a-204d of the bottom electrode structure 204 are etched to form the trenches 202a-202c. The columns 204a-204d of the bottom electrode structure 204 may function as a self-aligned mask when etching the portions of the ILD layers 114b-114e and the portions of the ESLs 116a-116e between the columns 204a-204d. An etch tool may be used to etch the portions of the ILD layers 114b-114e and the portions of the ESLs 116a-116e between the columns 204a-204d to form the trenches 202a-202c. In some implementations, the etch operation includes a dry etch operation (e.g., a plasma-based etch operation, a gas-based etch operation), a wet chemical etch operation, and/or another type of etch operation.

As shown in FIG. 4G, the insulator layer 208 of the trench capacitor structure 126 is formed on the sidewalls and on the bottom surfaces of the trenches 202a-202c. The insulator layer 208 may be conformally deposited such that the insulator layer 208 conforms to the profile of the trenches 202a-202c. In other words, the insulator layer 208 may be conformally deposited such that the insulator layer 208 conforms to the sidewalls of the trenches 202a-202c and the top surface of the bottom conductive structure 204e of the bottom electrode structure 204. The insulator layer 208 may continuously span between the trenches 202a-202c such that a single continuous insulator layer 208 is included in and between the trenches 202a-202c. A deposition tool may deposit the insulator layer 208 using a conformal deposition technique such as CVD and/or ALD, among other examples.

As shown in FIG. 4H, the trenches 202a-202c may be filled in with material of the top electrode structure 206 of the trench capacitor structure 126 such that the columns 206a-206c are formed on the insulator layer 208 in the trenches 202a-202c. The material of the top electrode structure 206 may also be deposited above the trenches 202a-202c such that the material of the top electrode structure 206 merges above the trenches 202a-202c to form the top conductive structure 206d of the top electrode structure 206. A deposition tool may be used to deposit the top electrode structure 206 using a CVD technique, a PVD technique, an ALD technique, an electroplating technique, and/or another suitable deposition technique. The top electrode structure 206 may be deposited in one or more deposition operations.

As shown in FIG. 4I, the ILD layer 114f may be formed on the trench capacitor structure 126. The top contact structure 130 of the of the trench capacitor structure 126 may be formed in the ILD layer 114f such that the top contact structure 130 lands on, and is electrically connected with, the top conductive structure 206d of the top electrode structure 206.

A deposition tool may be used to deposit the ILD layer 114f using a PVD technique, an ALD technique, a CVD technique, an oxidation technique, and/or another suitable deposition technique. The ILD layer 114f may be deposited in one or more deposition operations. In some implementations, a planarization tool may be used to perform a planarization operation (e.g., a CMP operation) to planarize the ILD layer 114f after the ILD layer 114f is deposited.

To form the top contact structure 130, a recess may be formed in the ILD layer 114f, and the top contact structure 130 may be deposited in the recess. In some implementations, a pattern in a photoresist layer is used to etch the ILD layer 114f to form the recess. In these implementations, a deposition tool may be used to form the photoresist layer on the ILD layer 114f (e.g., using a spin-coating technique and/or another suitable deposition technique). An exposure tool may be used to expose the photoresist layer to a radiation source to pattern the photoresist layer. A developer tool may be used to develop and remove portions of the photoresist layer to expose the pattern. An etch tool may be used to etch the ILD layer 114f based on the pattern to form the recess. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the ILD layer 114f based on a pattern.

A deposition tool may be used to deposit the material of the top contact structure 130 using a CVD technique, a PVD technique, an ALD technique, an electroplating technique, and/or another suitable deposition technique. The top contact structure 130 may be deposited in one or more deposition operations. In some implementations, a seed layer is first deposited, and the top contact structure 130 is deposited on the seed layer. In some implementations, a liner (e.g., a barrier liner, an adhesion liner) is first deposited, and the top contact structure 130 is deposited on the liner. In some implementations, a planarization tool is used to perform a planarization operation (e.g., a CMP operation) to planarize the top contact structure 130 after the top contact structure 130 is deposited.

As indicated above, FIGS. 4A-4I are provided as an example. Other examples may differ from what is described with regard to FIGS. 4A-4I.

FIG. 5 is a diagram of an example implementation 500 of a trench capacitor structure 126 described herein. As shown in FIG. 5, the example implementation 500 of the trench capacitor structure 126 illustrated in FIG. 5 includes a similar combination and arrangement of layers and structures as the example implementation 200 of the trench capacitor structure 126 illustrated in FIGS. 2A and 2B. However, in the example implementation 500, the interconnect structures 124 in the columns 204a-204d of the bottom electrode structure 204 of the trench capacitor structure 126 are substantially non-tapered such that the sidewalls of the interconnect structures 124 are approximately parallel. Thus, the trenches 202a-202c have substantially flat and uniform sidewalls, as shown in FIG. 5.

The interconnect structures 124 in the columns 204a-204d of the bottom electrode structure 204 of the trench capacitor structure 126 may be formed to have non-tapered sidewalls using process techniques such as anisotropic etching when forming the recesses for the interconnect structures 124. In some implementations, a plasma-based etch technique may be used to form the recesses for the interconnect structures 124 to achieve substantially vertical sidewalls for the recesses. In some implementations, a deep reactive ion etch technique (sometimes referred to as the “Bosch” etch technique) is used to achieve substantially vertical sidewalls for the recesses.

As indicated above, FIG. 5 is provided as an example. Other examples may differ from what is described with regard to FIG. 5.

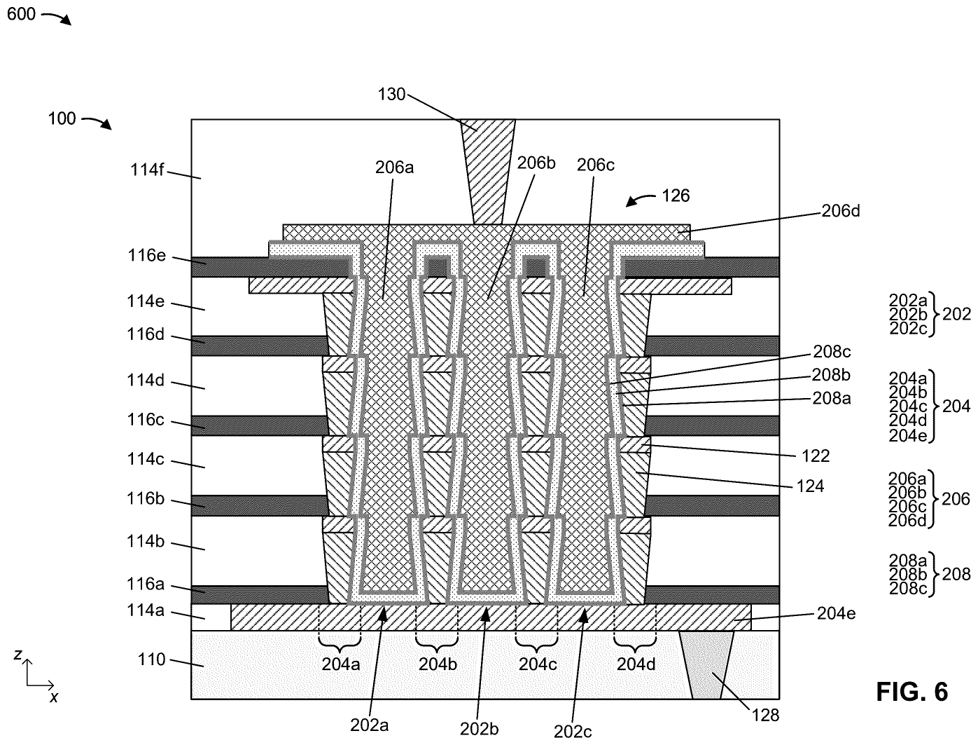

FIG. 6 is a diagram of an example implementation 600 of a trench capacitor structure 126 described herein. As shown in FIG. 6, the example implementation 600 of the trench capacitor structure 126 illustrated in FIG. 6 includes a similar combination and arrangement of layers and structures as the example implementation 200 of the trench capacitor structure 126 illustrated in FIGS. 2A and 2B. However, in the example implementation 600, the trench capacitor structure 126 includes an insulator layer 208 that includes is a multiple-layer stack that includes a plurality of dielectric layers. The plurality of dielectric layers may include a dielectric layer 208a on the sidewalls and on the bottom surfaces of the trenches 202a-202c (which correspond to sidewalls of the columns 204a-204d and the top surface of the bottom conductive structure 204e), a dielectric layer 208b on the dielectric layer 208a, and a dielectric layer 208c on the dielectric layer 208b. However, other quantities and arrangements of dielectric layers for the insulator layer 208 are within the scope of the present disclosure.

Including a plurality of dielectric layers 208a-208c for the insulator layer 208 enables the electrical properties of the insulator layer 208 to be tuned to achieve a particular performance for the trench capacitor structure 126. Additionally and/or alternatively, a plurality of dielectric layers 208a-208c may be included for the insulator layer 208 to facilitate adhesion between the insulator layer 208 and the bottom electrode structure 204, and/or to facilitate adhesion between the insulator layer 208 and the top electrode structure 206.

In some implementations, the multiple-layer stack of the insulator layer 208 includes a low-k layer/high-k layer/low-k layer stack. In these implementations, the dielectric layer 208a is a low-k dielectric layer, the dielectric layer 208b is a high-k dielectric layer, and the dielectric layer 208c is a low-k dielectric layer. For example, the insulator layer 208 may include an SiO₂/HfO₂/SiO₂ layer stack. In some implementations, the multiple-layer stack of the insulator layer 208 includes a high-k layer/high-k layer/high-k layer stack. In these implementations, the dielectric layer 208a is a first high-k dielectric layer, the dielectric layer 208b is a second high-k dielectric layer, and the dielectric layer 208c is a third high-k dielectric layer. For example, the insulator layer 208 may include a ZrO₂/Al₂O₃/ZrO₂ (ZAZ) layer stack. In some implementations, the multiple-layer stack of the insulator layer 208 includes another combination of high-k dielectric layers and/or low-k dielectric layers.

The example implementation 600 of the trench capacitor structure 126 illustrated in FIG. 6 may be formed using techniques and processes similar to those illustrated and described in connection with FIGS. 4A-4I. However, the operation for forming the insulator layer 208 described in connection with FIG. 4G may include a multiple-step deposition process to form the multiple-layer stack of the insulator layer 208 in the example implementation 600 of the trench capacitor structure 126 illustrated in FIG. 6. For example, a deposition tool may be used to deposit the dielectric layer 208a in a first deposition operation using an ALD technique, a CVD technique, and/or another suitable conformal deposition technique. A deposition tool may be used to deposit the dielectric layer 208b in a second deposition operation using an ALD technique, a CVD technique, and/or another suitable conformal deposition technique. A deposition tool may be used to deposit the dielectric layer 208c in a third deposition operation using an ALD technique, a CVD technique, and/or another suitable conformal deposition technique. The dielectric layers 208a-208c may each be deposited as a continuous layer that extends along the sidewalls of the trenches 202a-202c, that extends along the bottom surfaces of the trenches 202a-202c, and that extend between the trenches 202a-202c.

In some implementations, a thickness of the dielectric layer 208a is included in a range of approximately 1 nanometer to approximately 1 micron. In some implementations, a thickness of the dielectric layer 208b is included in a range of approximately 1 nanometer to approximately 1 micron. In some implementations, a thickness of the dielectric layer 208c is included in a range of approximately 1 nanometer to approximately 1 micron. However, other values and ranges are within the scope of the present disclosure.

In some implementations, the ratio of the thickness of the dielectric layer 208b to the dielectric layer 208a may be approximately 1:1 to approximately 2:1. In some implementations, the ratio of the thickness of the dielectric layer 208b to the dielectric layer 208c may be approximately 1:1 to approximately 2:1. In some implementations, the ratio of the thickness of the dielectric layer 208a to the dielectric layer 208c may be approximately 1:2 to approximately 2:1. However, other values and ranges are within the scope of the present disclosure.

As indicated above, FIG. 6 is provided as an example. Other examples may differ from what is described with regard to FIG. 6.

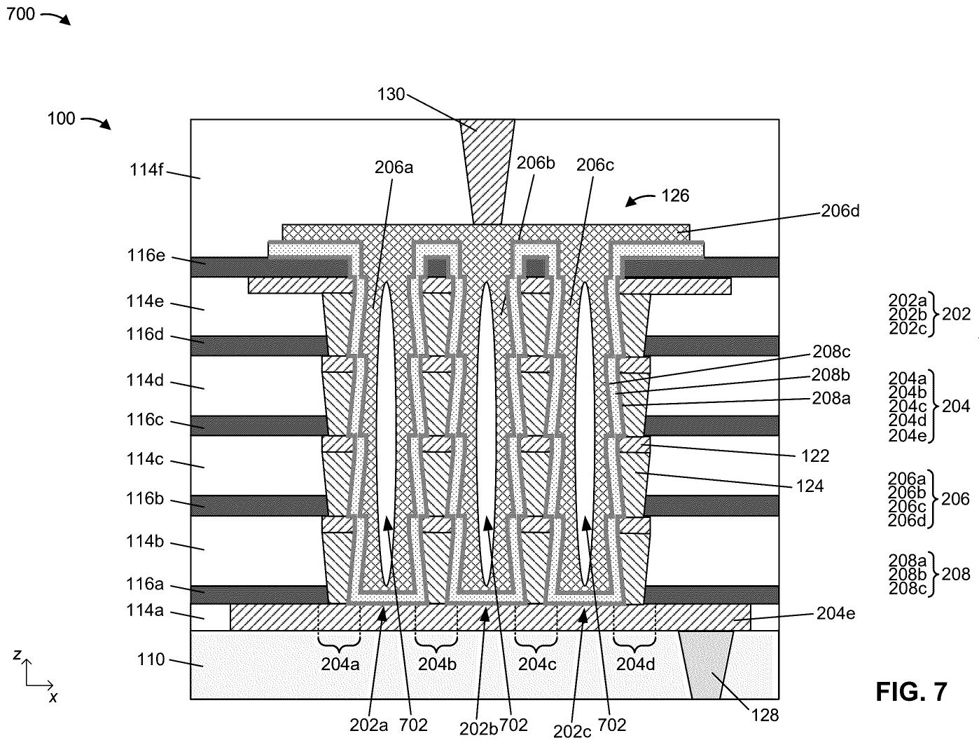

FIG. 7 is a diagram of an example implementation 700 of a trench capacitor structure 126 described herein. As shown in FIG. 7, the example implementation 700 of the trench capacitor structure 126 illustrated in FIG. 7 includes a similar combination and arrangement of layers and structures as the example implementation 600 of the trench capacitor structure 126 illustrated in FIG. 6. However, in the example implementation 700, the columns 206a-206c of the top electrode structure 206 of the trench capacitor structure 126 each include an airgap 702 that extends into a trench 202. For example, the column 206a includes an airgap 702 that extends into the trench 202a, the column 206b includes an airgap 702 that extends into the trench 202b, and/or the column 206c includes an airgap 702 that extends into the trench 202c, among other examples.

The airgap 702 in the column 206a of the top electrode structure 206 may extend between a top and a bottom of the trench 202a. Thus, the airgap 702 in the column 206a vertically spans a plurality of metallization structures 122 and a plurality of interconnect structures 124 in the columns 204a and 204b of the bottom electrode structure 204 that define the trench 202a. Similarly, the airgap 702 in the column 206b of the top electrode structure 206 may extend between a top and a bottom of the trench 202b, and the airgap 702 in the column 206c of the top electrode structure 206 may extend between a top and a bottom of the trench 202c. The airgaps 702 may be formed in the columns 206a-206c of the top electrode structure 206 to provide stress relief in the trench capacitor structure 126. Stresses may be exerted on the trench capacitor structure 126 due to vibration and/or due to thermal expansion and contraction, among other examples. The airgaps 702 enable the stresses in the trench capacitor structure 126 to be balanced, which reduces the likelihood of cracking and delamination in the layers and/or structures of the trench capacitor structure 126.

The airgaps 702 may be formed using deposition techniques during the operations for forming the top electrode structure 206 described in connection with FIG. 4H. For example, the material of the top electrode structure 206 may be deposited in the trenches 202a-202c at a high deposition rate. The high deposition rate results in the accumulation of material of the top electrode structure 206 at the top of the trenches 202a-202c at a faster rate than at the middle of the trenches 202a-202c. Thus, the material of the top electrode structure 206 merges at the top of the trenches 202a-202c before the trenches 202a-202c can be fully filled with the material of the top electrode structure 206, resulting in formation of the airgaps 702. In some implementations, a PVD technique, a CVD technique, and/or another deposition technique in which a high deposition rate may be achieved for the material of the top electrode structure 206 may be used to deposit the material of the top electrode structure 206.

As indicated above, FIG. 7 is provided as an example. Other examples may differ from what is described with regard to FIG. 7.

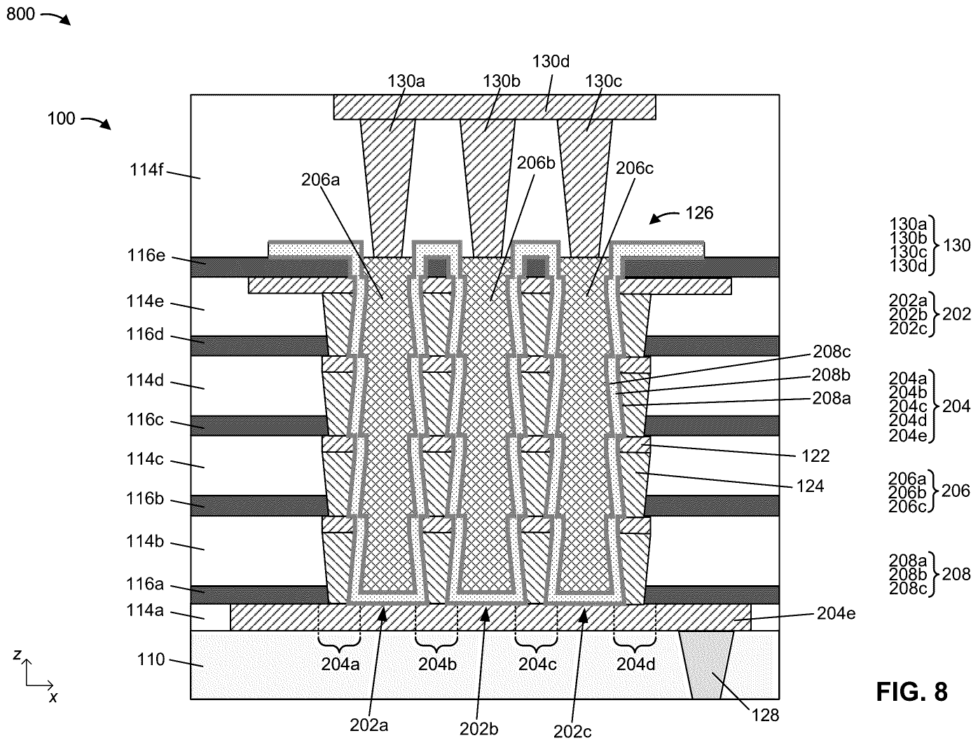

FIG. 8 is a diagram of an example implementation 800 of a trench capacitor structure 126 described herein. As shown in FIG. 8, the example implementation 800 of the trench capacitor structure 126 illustrated in FIG. 8 includes a similar combination and arrangement of layers and structures as the example implementation 600 of the trench capacitor structure 126 illustrated in FIG. 6. However, in the example implementation 800, the top conductive structure 206d of the top electrode structure 206 is omitted, and the columns 206a-206c of the top electrode structure 206 are physically discontinuous. Thus, the columns 206a-206c are not directly electrically coupled and are instead electrically coupled through the top contact structure 130.

The top contact structure 130 includes a plurality of top contact structures 130a-130c and a horizontally elongated metallization structure 130d that electrically coupled the top contact structures 130a-130c. Each of the columns 206a-206c may be physically coupled to one or more of the top contact structures 130a-130c. For example, the column 206a may be physically coupled to the top contact structure 130a, the column 206b may be physically coupled to the top contact structure 130b, and the column 206c may be physically coupled to the top contact structure 130c. The horizontally elongated metallization structure 130d electrically couples the top contact structures 130a-130c together so that the columns 206a-206c are electrically coupled in parallel.

As further shown in FIG. 8, the insulator layer 208 is similarly discontinuous between the trenches 202a-202c. Thus, the insulator layer 208 includes a plurality of discontinuous segments. A segment of the insulator layer 208 is included on the sidewalls and on the bottom surface of the trench 202a, and is therefore located between the bottom electrode structure 204 and the column 206a of the top electrode structure 206. A segment of the insulator layer 208 is included on the sidewalls and on the bottom surface of the trench 202b, and is therefore located between the bottom electrode structure 204 and the column 206b of the top electrode structure 206. A segment of the insulator layer 208 is included on the sidewalls and on the bottom surface of the trench 202c, and is therefore located between the bottom electrode structure 204 and the column 206c of the top electrode structure 206.

As indicated above, FIG. 8 is provided as an example. Other examples may differ from what is described with regard to FIG. 8.

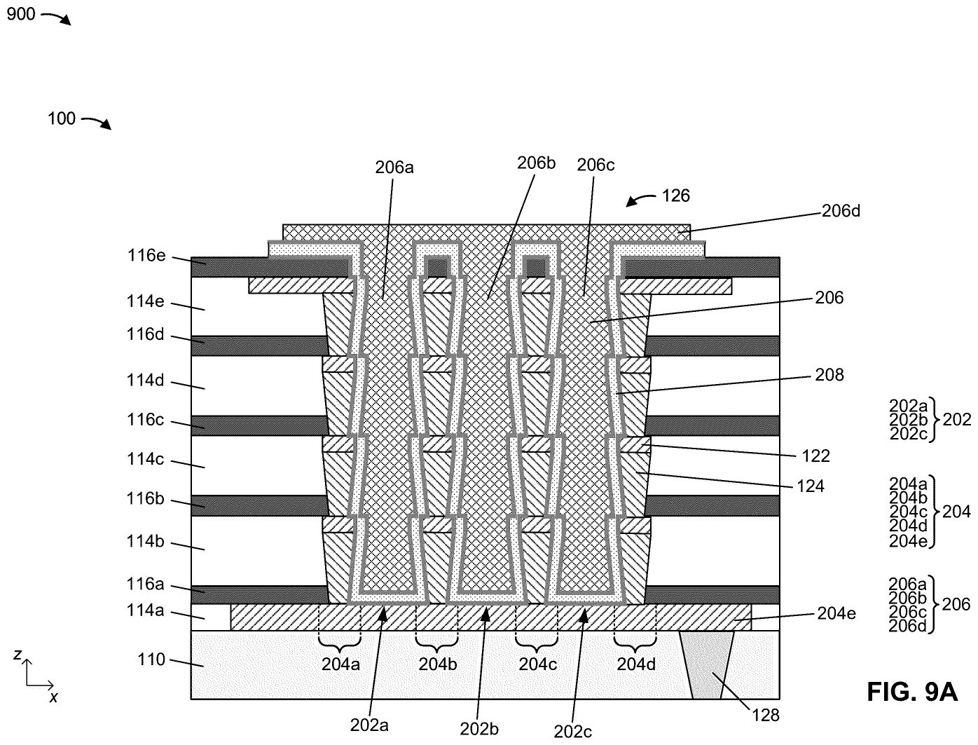

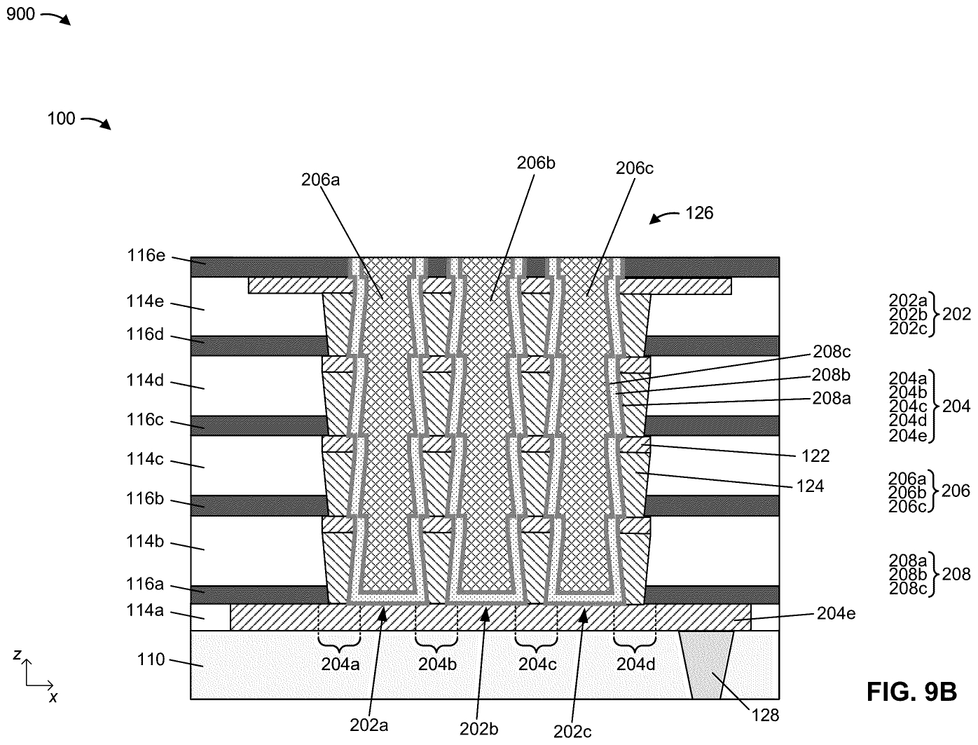

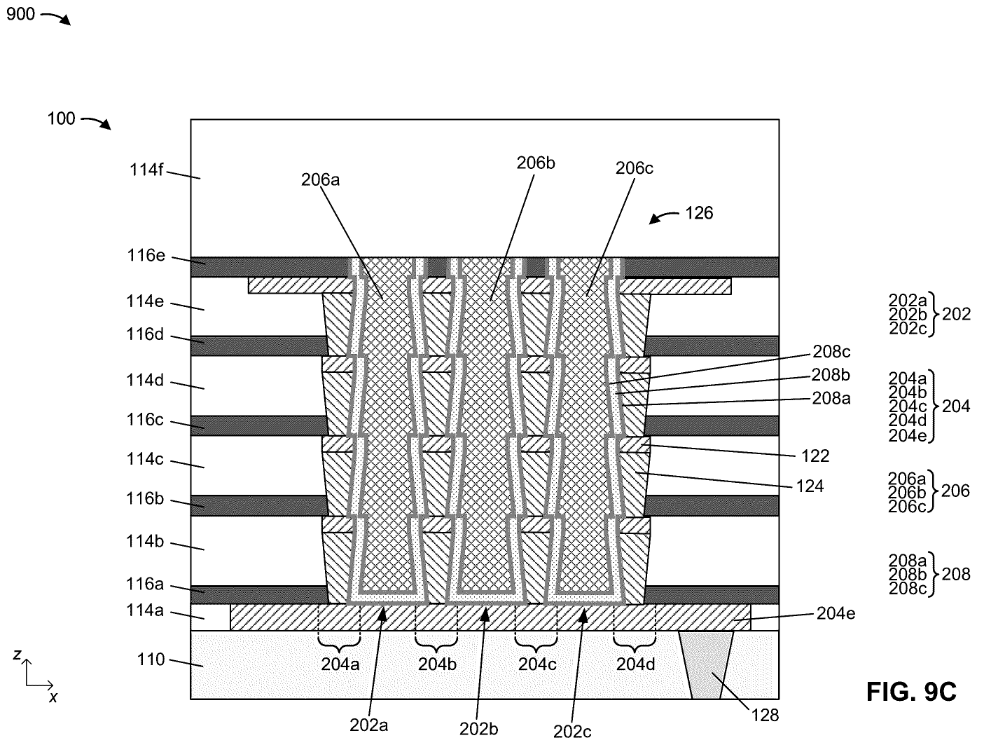

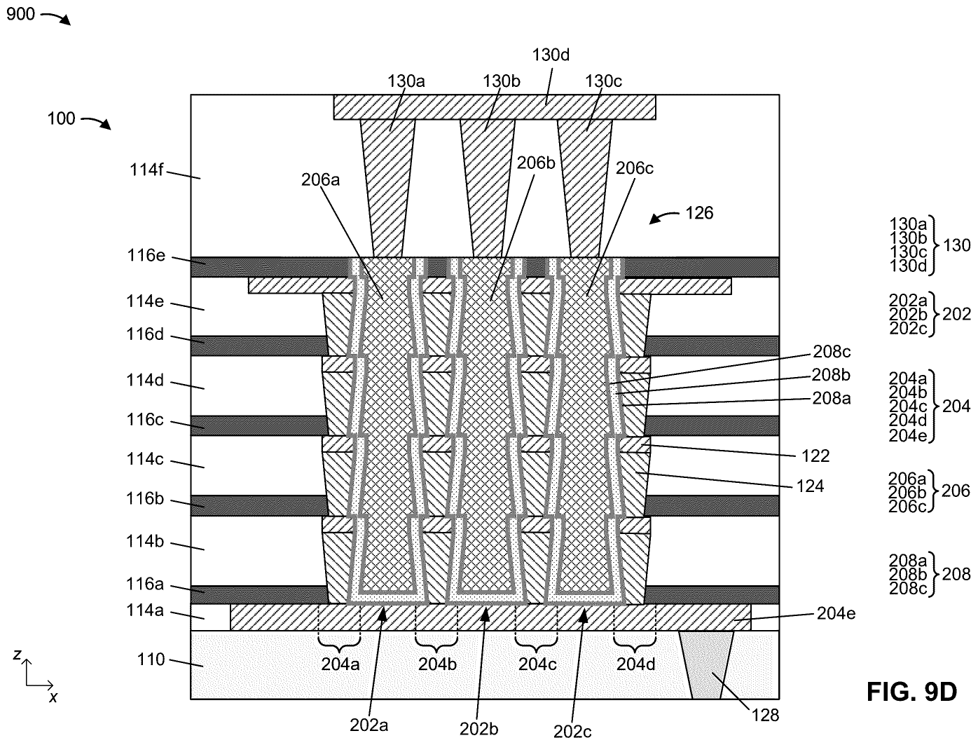

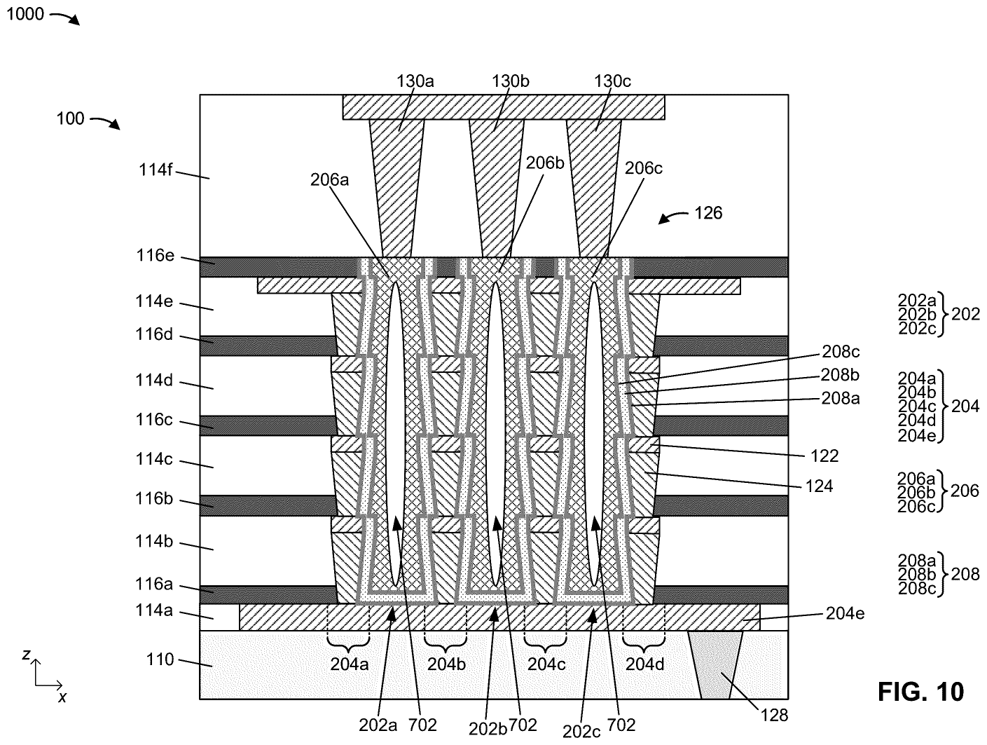

FIGS. 9A-9D are diagrams of an example implementation 900 of forming a trench capacitor structure 126 described herein. While FIGS. 9A-9D illustrate an example of forming the example implementation 800 of the trench capacitor structure 126 illustrated in FIG. 8, the techniques and operations described in connection with FIGS. 9A-9D may be performed to form other implementations of trench capacitor structures 126 described herein, including in connection with FIGS. 10 and/or 11A-11C, among other examples.

In some implementations, one or more of the semiconductor processing operations described in connection with FIGS. 9A-9D may be performed using one or more semiconductor processing tools, such as a deposition tool, an exposure tool, a developer tool, an etch tool, a planarization tool, a wafer/die transport tool, and/or another type of semiconductor processing tool. In some implementations, one or more of the semiconductor processing operations described in connection with FIGS. 9A-9D may be performed as part of the process for forming the semiconductor device 100 (or another semiconductor device) described in connection with FIGS. 3A-3D.

As shown in FIG. 9A, the operations illustrated and described in connection with FIGS. 4A-4H may be performed to form the bottom contact structure 128, the bottom electrode structure 204, the insulator layer 208, and the top electrode structure 206.

As shown in FIG. 9B, prior to formation of the ILD layer 114f on the trench capacitor structure 126, a planarization tool may be used to perform a planarization operation, such as a CMP operation or another type of planarization operation, to planarize the insulator layer 208, and the top electrode structure 206 of the trench capacitor structure 126. In the planarization operation, the top conductive structure 206d of the top electrode structure 206 is removed, along with the segments of the insulator layer 208 on the ESL 116e. As a result, the columns 206a-206c of the top electrode structure 206 are discontinuous between the trenches 202a-202c, as are the discontinuous segments of the insulator layer 208. Moreover, the ends of the segment in the trench 202a may be located at the top of the trench 202a, the ends of the segment in the trench 202b may be located at the top of the trench 202b, and the ends of the segment in the trench 202c may be located at the top of the trench 202c.

The planarization operation may stop on the ESL 116e, and therefore the ESL 116e may function as a stop layer for the planarization operation. After the planarization operation, the tops of the columns 206a-206c, the ends of the discontinuous segments of the insulator layer 208, and the top surface of the ESL 116e may be approximately co-planar.

As shown in FIG. 9C, the ILD layer 114f may be formed on the trench capacitor structure 126 after the planarization operation. Thus, the ILD layer 114f is in contact with the tops of the columns 206a-206c of the top electrode structure 206, and is in contact with the ends of the discontinuous segments of the insulator layer 208.

As shown in FIG. 9D, the top contact structures 130a-130c and the horizontally elongated metallization structure 130d are formed in the ILD layer 114f. For example, a recess may be formed in the ILD layer 114f above each of the trenches 202a-202c and the corresponding columns 206a-206c of the top electrode structure 206. The electrically conductive material of the top contact structures 130a-130c may be formed in the recesses above the columns 206a-206c so that the top contact structures 130a-130c land on the columns 206a-206c, respectively. A recess may be formed in the ILD layer 114f for the horizontally elongated metallization structure 130d, and the horizontally elongated metallization structure 130d may be formed in the recess.

In some implementations, the recesses for the top contact structures 130a-130c and for the horizontally elongated metallization structure 130d may be formed as a dual damascene recess, where the vias of the dual damascene recess corresponds to the recesses for the top contact structures 130a-130c, and the trench of the dual damascene recess corresponds to the recess for the horizontally elongated metallization structure 130d. The dual damascene recess may be formed using a via-first process (e.g., in which the vias of the dual damascene recess corresponding to the recesses for the top contact structures 130a-130c are formed first, followed by the trench of the dual damascene recess corresponding to the recess for the horizontally elongated metallization structure 130d) or a trench-first process (e.g., in which the trench of the dual damascene recess corresponding to the recess for the horizontally elongated metallization structure 130d is formed first, followed by the vias of the dual damascene recess corresponding to the recesses for the top contact structures 130a-130c). In these implementations, the top contact structures 130a-130c and the horizontally elongated metallization structure 130d may be deposited together in the dual damascene recess.

As indicated above, FIGS. 9A-9D are provided as an example. Other examples may differ from what is described with regard to FIGS. 9A-9D.

FIG. 10 is a diagram of an example implementation 1000 of a trench capacitor structure 126 described herein. As shown in FIG. 10, the example implementation 1000 of the trench capacitor structure 126 illustrated in FIG. 10 includes a similar combination and arrangement of layers and structures as the example implementation 800 of the trench capacitor structure 126 illustrated in FIG. 8. However, in the example implementation 1000, the columns 206a-206c of the top electrode structure 206 of the trench capacitor structure 126 each include an airgap 702 that extends into a trench 202, similar to the example implementation 700 of the trench capacitor structure 126 in FIG. 7. For example, the column 206a includes an airgap 702 that extends into the trench 202a, the column 206b includes an airgap 702 that extends into the trench 202b, and/or the column 206c includes an airgap 702 that extends into the trench 202c, among other examples.

The airgap 702 in the column 206a of the top electrode structure 206 may extend between a top and a bottom of the trench 202a. Thus, the airgap 702 in the column 206a vertically spans a plurality of metallization structures 122 and a plurality of interconnect structures 124 in the columns 204a and 204b of the bottom electrode structure 204 that define the trench 202a. Similarly, the airgap 702 in the column 206b of the top electrode structure 206 may extend between a top and a bottom of the trench 202b, and the airgap 702 in the column 206c of the top electrode structure 206 may extend between a top and a bottom of the trench 202c. The airgaps 702 may be formed in the columns 206a-206c of the top electrode structure 206 to provide stress relief in the trench capacitor structure 126. Stresses may be exerted on the trench capacitor structure 126 due to vibration and/or due to thermal expansion and contraction, among other examples. The airgaps 702 enable the stresses in the trench capacitor structure 126 to be balanced, which reduces the likelihood of cracking and delamination in the layers and/or structures of the trench capacitor structure 126.

The airgaps 702 may be formed using deposition techniques during the operations for forming the top electrode structure 206 described in connection with FIG. 4H. For example, the material of the top electrode structure 206 may be deposited in the trenches 202a-202c at a high deposition rate. The high deposition rate results in the accumulation of material of the top electrode structure 206 at the top of the trenches 202a-202c at a faster rate than at the middle of the trenches 202a-202c. Thus, the material of the top electrode structure 206 merges at the top of the trenches 202a-202c before the trenches 202a-202c can be fully filled with the material of the top electrode structure 206, resulting in formation of the airgaps 702. In some implementations, a PVD technique, a CVD technique, and/or another deposition technique in which a high deposition rate may be achieved for the material of the top electrode structure 206 may be used to deposit the material of the top electrode structure 206.

As indicated above, FIG. 10 is provided as an example. Other examples may differ from what is described with regard to FIG. 10.

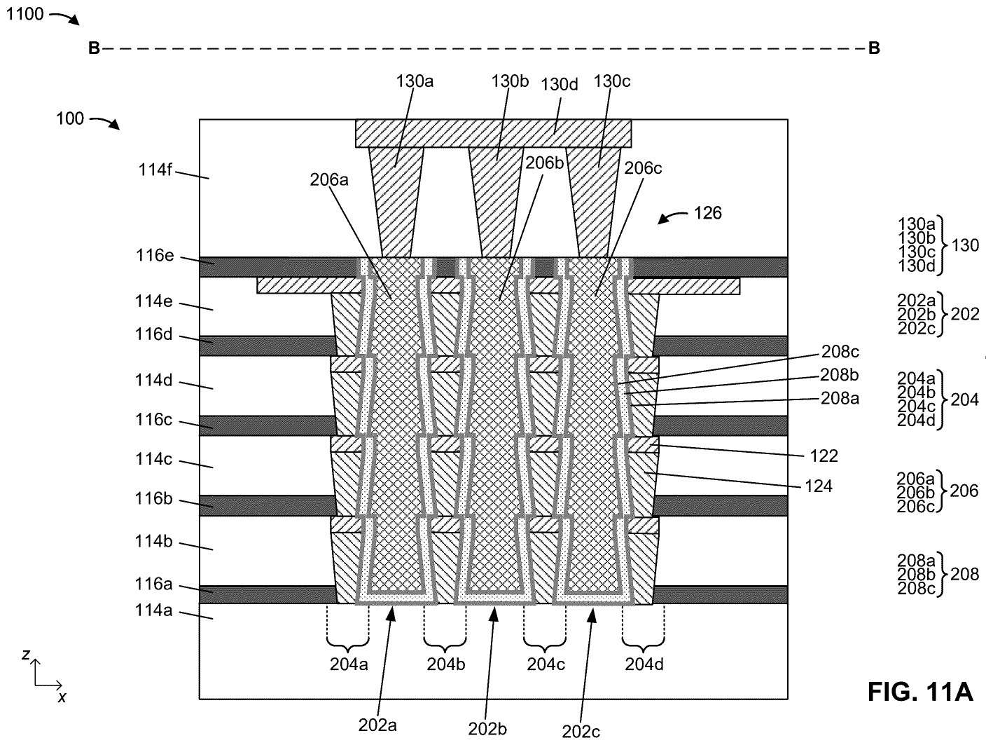

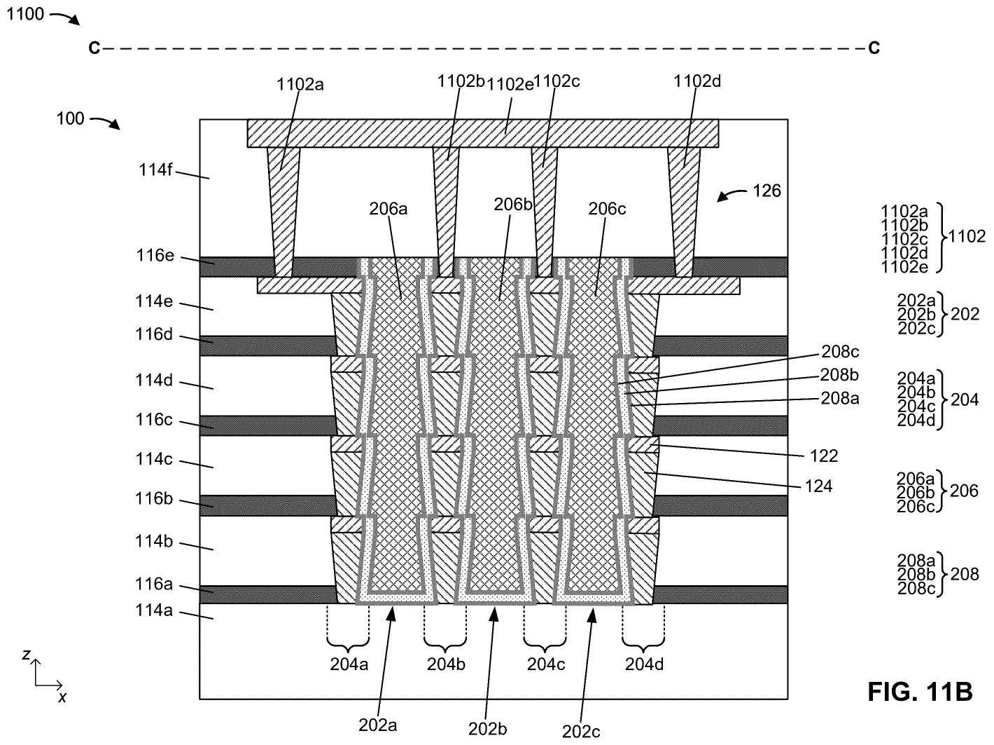

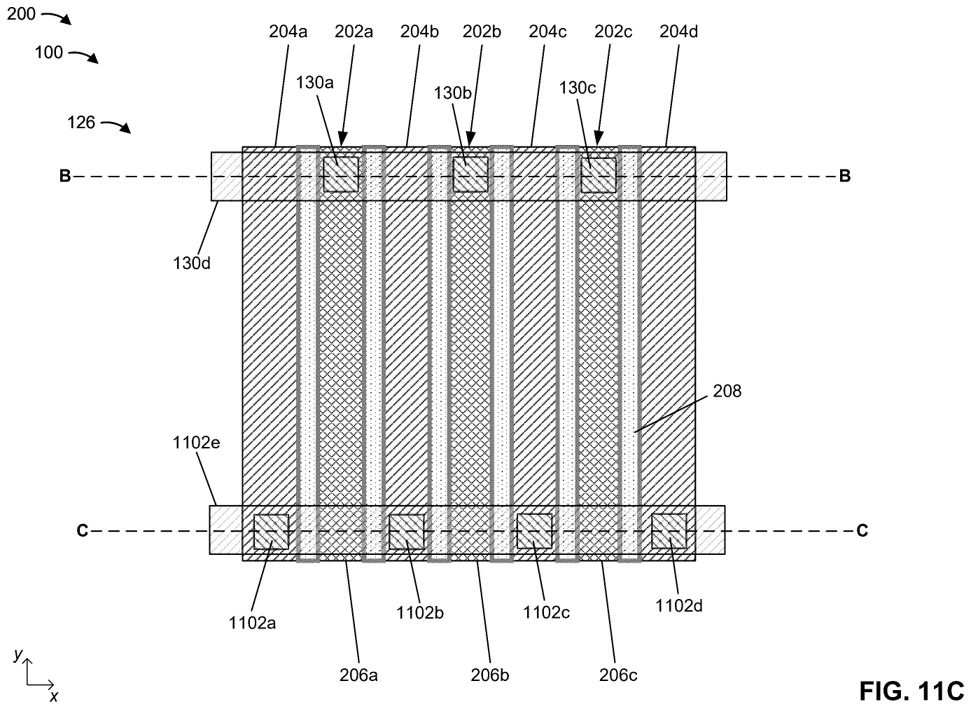

FIGS. 11A-11C are diagrams of an example implementation 1100 of a trench capacitor structure 126 described herein. As shown in a cross-section view of the trench capacitor structure 126 in FIG. 11A, the example implementation 1100 of the trench capacitor structure 126 illustrated includes a similar combination and arrangement of layers and structures as the example implementation 800 of the trench capacitor structure 126 illustrated in FIG. 8. For example, the top conductive structure 206d of the top electrode structure 206 is omitted, and the columns 206a-206c of the top electrode structure 206 are physically discontinuous. The top contact structure 130 includes a plurality of top contact structures 130a-130c and a horizontally elongated metallization structure 130d that electrically coupled the top contact structures 130a-130c. Each of the columns 206a-206c is physically coupled to an interconnect structure of the top contact structure 130.

However, and as shown in a cross-section view of the trench capacitor structure 126 in FIG. 11B, the bottom conductive structure 204e is also omitted from the bottom electrode structure 204. Instead, the columns 204a-204d of the bottom electrode structure 204 are electrically coupled through another top contact structure 1102. The top contact structure 1102 includes a plurality of top contact structures 1102a-1102d and a horizontally elongated metallization structure 1102e that electrically coupled top contact structures 1102a-1102d. Each of the columns 204a-204d may be physically coupled to one or more of the top contact structures 1102a-1102d. For example, the column 204a may be physically coupled to the top contact structure 1102a, the column 204b may be physically coupled to the top contact structure 1102b, the column 204c may be physically coupled to the top contact structure 1102c, and the column 204d may be physically coupled to the top contact structure 1102d. The horizontally elongated metallization structure 1102e electrically couples the top contact structures 1102a-1102d together so that the columns 204a-204d are electrically coupled in parallel.

The top contact structures 1102a-1102d may extend through the ESL 116e and may physically contact the columns 204a-204d, respectively. In some implementations, the outer columns (e.g., the columns 204a and 204d) may include lateral extensions on which the top contact structures 1102a and 1102d may land.

FIG. 11C illustrates a top view of the example implementation 1100 of the trench capacitor structure 126, and illustrates the location of the cross-section view of FIG. 11A along the line B-B and the location of the cross-section view of FIG. 11B along the line C-C. As shown in FIG. 11C, the top contact structures 1102a-1102d and the horizontally elongated metallization structure 1102e of the top contact structure 1102 may be located at a first side of the trenches 202a-202c of the trench capacitor structure 126, and the top contact structures 206a-206c and the top conductive structure 206d of the top electrode structure 206 may be located at a second side of the trenches 202a-202c of the trench capacitor structure 126 opposing the first side. However, other locations along the trenches 202a-202c for the top contact structures 1102a-1102d and the horizontally elongated metallization structure 1102e of the top contact structure 1102, and/or for the top contact structures 206a-206c and the top conductive structure 206d of the top electrode structure 206, are within the scope of the present disclosure.

As indicated above, FIGS. 11A-11C are provided as an example. Other examples may differ from what is described with regard to FIGS. 11A-11C.

FIGS. 12A and 12B are diagrams of an example of a semiconductor device 1200 described herein. FIG. 12A illustrates a top view of the semiconductor device 1200. As shown in FIG. 12A, the semiconductor device 1200 may include a display device that includes a display pixel array 1202. The display pixel array 1202 includes a plurality of display pixels 1204 configured to collectedly generate an image and/or video. In some implementations, the display pixels 1204 are arranged in a grid, as shown in the example in FIG. 12A. However, other arrangements of display pixels 1204 for the display pixel array 1202 are within the scope of the present disclosure. In some implementations, the display pixels 1204 include OLED display pixels, and the display pixel array 1202 includes an OLED display. However, other types of display pixels and display pixel arrays are within the scope of the present disclosure.

As further shown in FIG. 12A, a display pixel 1204 may include a plurality of subpixels 1206. For example, a display pixel 1204 may include a subpixel 1206a that is configured to emit light of a first color (e.g., red light), a subpixel 1206b that is configured to emit light of a second color (e.g., green light), and subpixel 1206c that is configured to emit light of a third color (e.g., blue light). However, other configurations and combinations of subpixels 1206 for the display pixels 1204 are within the scope of the present disclosure. Two or more subpixels 1206 of a display pixel 1204 may be the same size and/or shape, two or more subpixels 1206 of a display pixel 1204 may be different sizes and/or different shapes, or a combination thereof.

FIG. 12B illustrates cross-section views of an example display pixel 1204 along line D-D and line E-E in FIG. 12A. The cross-section views in FIG. 12B illustrate an example structural arrangement of subpixels 1206a-1206c of the display pixel 1204. As shown in FIG. 12B, the semiconductor device 1200 may include a microdisplay device in that the subpixels 1206a-1206c of the display pixel array 1202 are included on a circuitry layer 1208 of the semiconductor device 1200. Thus, the semiconductor device 1200 may include an OLED-on-silicon device, a display-on-silicon device, and/or another type of microdisplay device in which a display pixel array 1202 is integrated on the semiconductor device 1200 with CMOS integrated circuits.

As shown in FIG. 12B, the circuitry layer 1208 of the semiconductor device 1200 includes a device layer 1210 and an interconnect layer 1212 of the semiconductor device 1200. The device layer 1210 may include a semiconductor layer 1214 corresponding to a portion of a semiconductor wafer on which the semiconductor device 1200 was formed. The semiconductor layer 1214 may include a silicon (Si) substrate, a substrate formed of a material including silicon, a III-V compound semiconductor material substrate such as gallium arsenide (GaAs), a silicon on insulator (SOI) substrate, or another type of semiconductor substrate.

The device layer 1210 includes integrated circuit devices 1216 in and/or on the semiconductor layer 1214. The integrated circuit devices 1216 may include the components of drive circuits included in the subpixel circuits of the subpixels 1206a-1206c. For example, the integrated circuit devices 1216 may include switching transistors, driving transistors, and/or other components of the drive circuits. The transistors (e.g., the switching transistors, the driving transistors) of the drive circuits may be implemented as planar transistors, finFETs, nanostructure transistors (e.g., GAA transistors, nanosheet transistors, nanowire transistors), and/or another type of transistors in and/or on the semiconductor layer 1214.

The interconnect layer 1212 includes conductive structures that interconnect the integrated circuit devices 1216 of the drive circuits, and electrically connect the integrated circuit devices 1216 of the drive circuits with the subpixels 1206a-1206c. The interconnect layer 1212 includes one or more dielectric layers 1218 that are arranged in a direction (e.g., z-direction) that is approximately perpendicular to the semiconductor layer 1214. The dielectric layer(s) 1218 may each include backend dielectric layers (e.g., ILD layers, intermetal dielectric (IMD) layers) and ESLs that are arranged in an alternating manner in the interconnect layer 1212. The dielectric layer(s) 1218 may each include an oxide (e.g., a silicon oxide (SiOₓ) and/or another oxide material), an undoped silicate glass (USG), a boron-containing silicate glass (BSG), a fluorine-containing silicate glass (FSG), an extreme low dielectric constant (ELK) dielectric material having a dielectric constant that is less than approximately 2.5, a silicon nitride (SiₓN_{y}), silicon carbide (SiC), silicon oxynitride (SiON), and/or another suitable dielectric material.

The conductive structures in the dielectric layer(s) 1218 of the interconnect layer 1212 may include metallization structures 1220 (e.g., trenches, conductive lines) that are interconnected by interconnect structures 1222 (e.g., vias). The metallization structures 1220 and interconnect structures 1222 may each include one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials.

As further shown in FIG. 12B, one or more of the example implementations of trench capacitor structures 126 illustrated and described herein may be included in the interconnect layer 1212 of the semiconductor device 1200. The trench capacitor structure(s) 126 may be configured as storage capacitor(s) of the drive circuits of the subpixels 1206a-1206c. The trench capacitor structure(s) 126 may be included to stabilize drive signals and, therefore, the brightness of the subpixels 1206a-1206c (thereby increasing the brightness uniformity of the display pixel array 1202), and/or to reduce and/or minimize flicker for the subpixels 1206a-1206c.

The bottom electrode structure 204 of a trench capacitor structure 126 included in the interconnect layer 1212 of the semiconductor device 1200 may include a plurality of columns 204a-204d that each include a vertically alternating arrangement of metallization structures 1220 and interconnect structures 1222. The columns 204a-204d define the trenches of the trench capacitor structure 126, and the insulator layer 208 may be formed on the sidewalls of the trenches (corresponding to the sidewalls of the columns 204a-204d).

The device layer 1210 and the interconnect layer 1212 of the semiconductor device 1200 may be formed in a similar manner as the device layer 102 and the interconnect layer 104 of the semiconductor device 100, as described in connection with FIGS. 3A-3D. In some implementations, the display pixel array 1202 may be formed separately from the device layer 1210 and the interconnect layer 1212 of the semiconductor device 1200 (e.g., at a display panel manufacture), and may be bonded to the interconnect layer 1212 of the semiconductor device 1200 after the display pixel array 1202 is manufactured. In some implementations, the display pixel array 1202 is formed on the interconnect layer 1212 of the semiconductor device 1200.

As indicated above, FIGS. 12A and 12B are provided as an example. Other examples may differ from what is described with regard to FIGS. 12A and 12B.

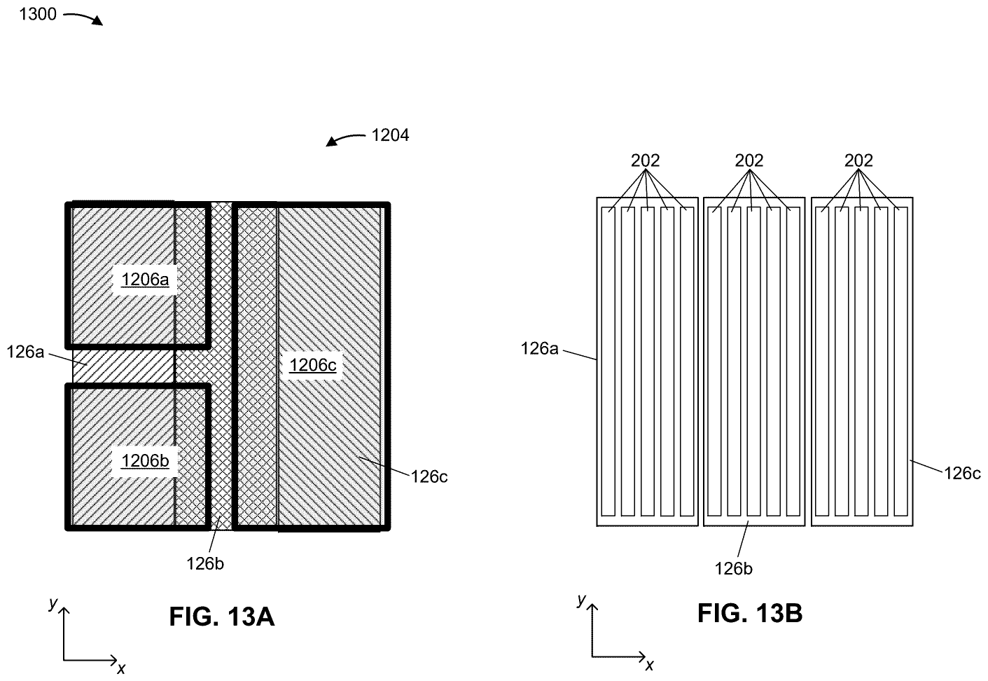

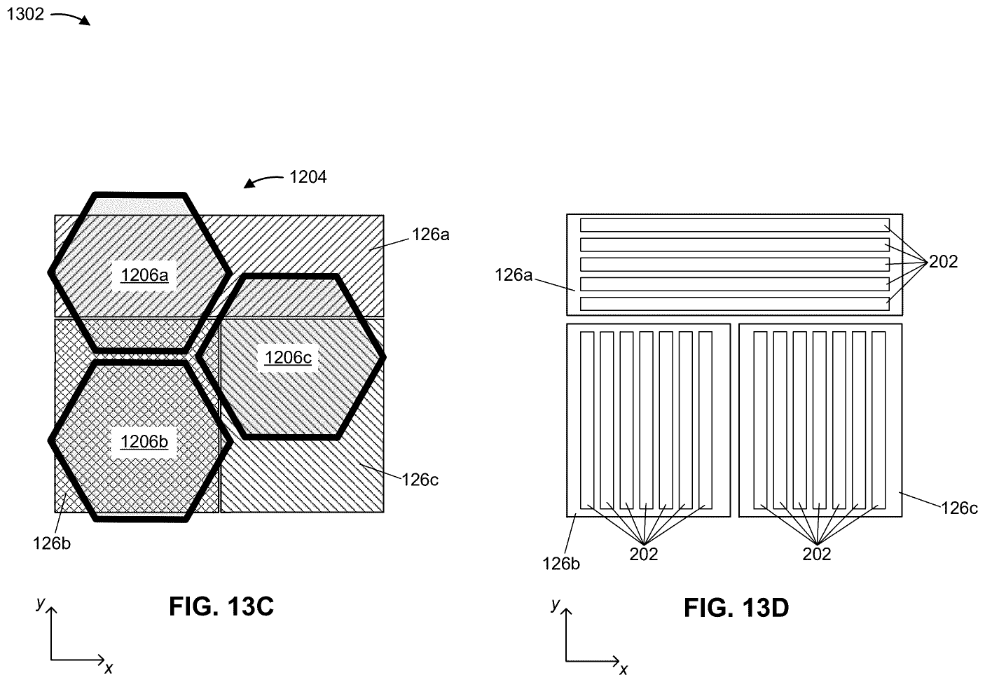

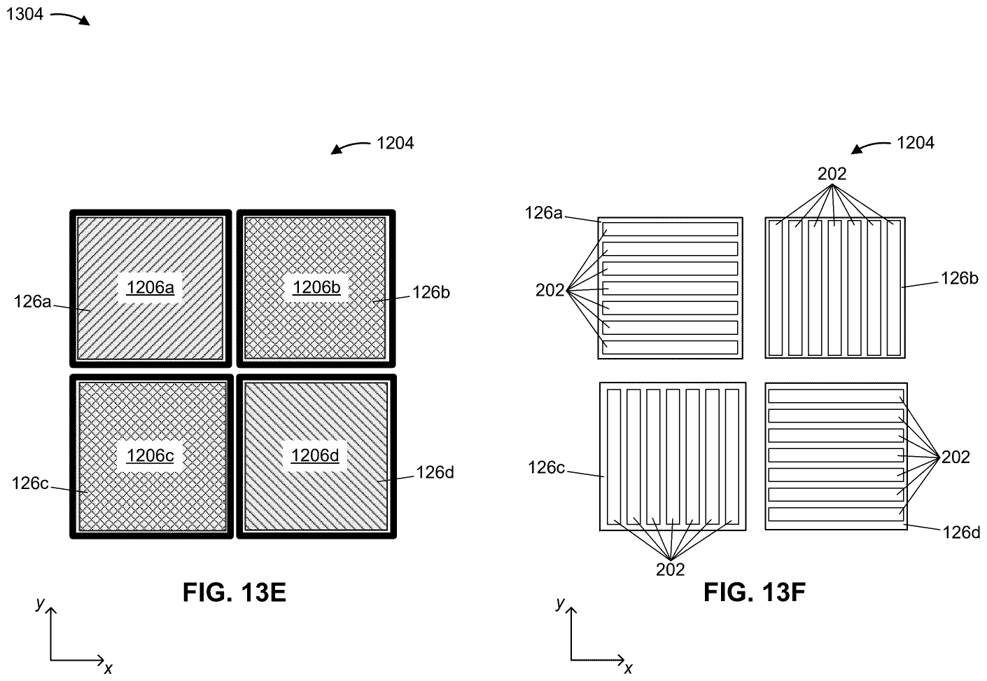

FIGS. 13A-13F are diagrams of example implementations of top view layouts for subpixels 1206a-1206c and associated trench capacitor structures 126 of a display pixel 1204 of the semiconductor device 1200 described herein.

FIGS. 13A and 13B illustrate an example implementation 1300 in which the subpixels 1206a and 1206b are laterally adjacent in the y-direction, and the subpixel 1206c is laterally adjacent to the subpixels 1206a and 1206b in the x-direction. The subpixels 1206a and 1206b may each have an approximately square top view shape, and the subpixel 1206c may have an approximately rectangular top view shape. Each of the subpixels 1206a-1206c may be associated with a trench capacitor structure. For example, the subpixel 1206a may be electrically coupled to a trench capacitor structure 126a, the subpixel 1206b may be electrically coupled to a trench capacitor structure 126b, and the subpixel 1206c may be electrically coupled to a trench capacitor structure 126c. The trench capacitor structures 126a-126c may be located below the subpixels 1206a-1206c and may be laterally arranged in the x-direction. The trench capacitor structures 126a-126c may be approximately rectangular shaped in the top view, and the trenches 202 of each of the trench capacitor structures 126a-126c may extend in the y-direction and may be arranged in the x-direction. In some implementations, the trench capacitor structures 126a-126c include the same quantity of trenches 202. In some implementations, two or more of the trench capacitor structures 126a-126c include different quantities of trenches 202. In some implementations, the trench capacitor structures 126a-126c include trenches 202 of the same size and/or the same shape. In some implementations, two or more of the trench capacitor structures 126a-126c include trenches 202 that are different in size and/or that are different in shape. For example, the trenches 202 of the trench capacitor structure 126a may be larger in size (e.g., in length, width, and/or depth) than the trenches 202 of the trench capacitor structure 126b.

FIGS. 13C and 13D illustrate an example implementation 1302 in which the subpixels 1206a-1206c are all laterally adjacent to each other and each have an approximate hexagonal top view shape. The trench capacitor structures 126b and 126c are laterally adjacent in the x-direction, and the trench capacitor structure 126a is laterally adjacent to the trench capacitor structures 126b and 126c in the y-direction. The trench capacitor structures 126b and 126c may each have an approximately square top view shape, and the trench capacitor structure 126a may have an approximately rectangular top view shape. The trenches 202 of the trench capacitor structures 126b and 126c may extend in the y-direction and may be arranged in the x-direction. The trenches 202 of the trench capacitor structure 126a may extend in the x-direction and may be arranged in the y-direction.

FIGS. 13E and 13F illustrate an example implementation 1304 in which a display pixel 1204 includes subpixels 1206a-1206d are each have an approximate square top view shape. The subpixel 1206a and the subpixel 1206b may be laterally adjacent in the x-direction. The subpixel 1206a and the subpixel 1206c may be laterally adjacent in the y-direction. The subpixel 1206b and the subpixel 1206d may be laterally adjacent in the y-direction. The subpixel 1206c and the subpixel 1206d may be laterally adjacent in the x-direction.

The subpixels 1206a-1206d are respectively associated with trench capacitor structures 126a-126d. The trench capacitor structures 126a-126d each have an approximate square top view shape. The trench capacitor structures 126a and 126b are laterally adjacent in the x-direction. The trench capacitor structures 126a and 126c are laterally adjacent in the y-direction. The trench capacitor structures 126b and 126d are laterally adjacent in the y-direction. The trench capacitor structures 126c and 126d are laterally adjacent in the x-direction. The trenches 202 of the trench capacitor structures 126a and 126d may extend in the x-direction and may be arranged in the y-direction. The trenches 202 of the trench capacitor structures 126b and 126c may extend in the y-direction and may be arranged in the x-direction.

As indicated above, FIGS. 13A-13F are provided as examples. Other examples may differ from what is described with regard to FIGS. 13A-13F.

FIG. 14 is a diagram of an example semiconductor device 1400 described herein. The semiconductor device 1400 may include an example of a three-dimensional image sensor (e.g., a 3D CMOS image sensor (CIS)). The semiconductor device 1400 may be configured to be deployed in various implementations, such as digital cameras, video recorders, night-vision cameras, automotive sensors and cameras, and/or other types of light-sensing implementations.

As shown in FIG. 14, the semiconductor device 1400 may include a plurality of semiconductor dies, including a first semiconductor die 1402a and a second semiconductor die 1402b. The first semiconductor die 1402a and the second semiconductor die 1402b may be directly bonded together at a bonding interface 1404 such that the first semiconductor die 1402a and the second semiconductor die 1402b are stacked and vertically arranged in a z-direction in the semiconductor device 1400. The first semiconductor die 1402a may be referred to as an image sensor die and may include a pixel sensor array 1406. The first semiconductor die 1402a may further include a black level correction (BLC) region 1408, a bonding pad region 1410, and/or a seal ring region 1412, among other examples.

The pixel sensor array 1406 may include a plurality of pixel sensors 1414 arranged in an array. The pixel sensors 1414 may be configured to sense incident light and convert photons of the incident light to a photocurrent. The pixel sensors 1414 may be included in a device layer 1416 of the first semiconductor die 1402a. The pixel sensors 1414 may each include a photodiode 1418 that is configured to generate a photocurrent based on photons of incident light. The pixel sensors 1414 may further include a floating diffusion node 1420 in the device layer 1416 that is configured to temporarily store the photocurrent generated by an associated pixel sensor 1414, and may each include a transfer gate 1422 that is configured to control the flow of photocurrent from a photodiode 1418 to a floating diffusion node 1420. The pixel sensors 1414 may be formed by one or more semiconductor processing tools using various semiconductor processing techniques, such as photolithography, etching, deposition, CMP, and/or ion implantation, among other examples.

The BLC region 1408 includes a metal shielding layer over a portion of the device layer 1416 so that a baseline measurement of current in the device layer 1416 in the BLC region 1408 can be performed to determine the dark current (e.g., the current in the device layer 1416 that is generated from sources other than incident light such as heat) of the pixel sensor array 1406 so that the black level of the pixel sensor array 1406 can be adjusted to compensate for the dark current. The bonding pad region 1410 may include one or more conductive bonding pads (or e-pads) and/or metallization layers through which electrical connections between the semiconductor device 1400 and outside devices and/or external packaging may be established. The seal ring region 1412 may include an arrangement of metallization structures and interconnect structures to provide structural rigidity for the semiconductor device 1400 and to protect the semiconductor device 1400 from ingress of humidity and other contaminants.

As further shown in FIG. 14, the first semiconductor die 1402a may include an interconnect layer 1424 below and/or under the device layer 1416. The interconnect layer 1424 may include a dielectric region 1426 that includes one or more dielectric layers (e.g., ILD layers, ESL layers) and an arrangement of metallization structures 1428 and interconnect structures 1430 in the dielectric region 1426.

As further shown in FIG. 14, the second semiconductor die 1402b of the semiconductor device 1400 may include a device layer 1432, one or more integrated circuit devices 1434 included in the device layer 1432, and an interconnect layer 1436 above the device layer 1432. The interconnect layer 1436 may include a dielectric region 1438 that includes one or more dielectric layers (e.g., ILD layers, ESLs) and an arrangement of metallization structures 1440 and interconnect structures 1442 in the dielectric region 1438 of the interconnect layer 1436 of the second semiconductor die 1402b.

The first semiconductor die 1402a and the second semiconductor die 1402b may be bonded at the bonding interface 1404 by dielectric-to-dielectric bonds between the dielectric region 1426 of the first semiconductor die 1402a and the dielectric region 1438 of the second semiconductor die 1402b. Moreover, the first semiconductor die 1402a and the second semiconductor die 1402b may be bonded at the bonding interface 1404 by metal-to-metal bonds between bonding pads 1444 included in the interconnect layer 1424 of the first semiconductor die 1402a and bonding pads 1446 included in the interconnect layer 1436 of the second semiconductor die 1402b. The bonding pads 1444 may be electrically connected to the metallization structures 1428 and the interconnect structures 1430 in the interconnect layer 1424 by bonding vias 1448, and the bonding pads 1446 may be electrically connected to the metallization structures 1440 and the interconnect structures 1442 in the interconnect layer 1436 by bonding vias 1450.

As further shown in FIG. 14, one or more trench capacitor structures 126 are included in the semiconductor device 1400. The one or more trench capacitor structures 126 may be included in the dielectric region 1426 of the of the interconnect layer 1424 of the first semiconductor die 1402a. The bottom electrode structure 204 of a trench capacitor structure 126 included in the interconnect layer 1424 of the first semiconductor die 1402a may include a plurality of columns 204a-204d that each include a vertically alternating arrangement of metallization structures 1428 and interconnect structures 1430. The columns 204a-204d define the trenches of the trench capacitor structure 126, and the insulator layer 208 may be formed on the sidewalls of the trenches (corresponding to the sidewalls of the columns 204a-204d).

The one or more trench capacitor structures 126 may be configured to store a photocurrent associated with the plurality of pixel sensors 1414 in the pixel sensor array 1406. In some implementations, the one or more trench capacitor structures 126 are configured to store overflow photocurrent from the floating diffusion nodes 1420 of the pixel sensors 1414 to increase the full well capacity of the pixel sensors 1414. The one or more trench capacitor structures 126 may be referred to as lateral overflow integration (LOFIC) capacitors, and the semiconductor device 1400 may be referred to as a LOFIC CMOS image sensor. The one or more trench capacitor structures 126 increase the full well capacity of the pixel sensors 1414 in that photocurrent from the floating diffusion nodes 1420 of the pixel sensors 1414 may be transferred to the one or more trench capacitor structures 126, which enables additional photocurrent from the photodiodes 1418 to be transferred to the floating diffusion nodes 1420 during and/or after an exposure operation for the pixel sensor array 1406. This effectively extends the amount of photons that can be absorbed by the photodiodes 1418 before the photodiodes 1418 reach saturation, thereby enabling a high dynamic range (HDR) to be achieved for the pixel sensor array 1406.

In some implementations, the one or more trench capacitor structures 126 may be included to enable global shutter functionality to be implemented in the semiconductor device 1400. Another type of shutter effect, referred to as rolling shutter, is achieved through progressive exposure of the pixel sensors 1414 in the pixel sensor array 1406 to incident light. At the beginning of an exposure operation, the integrated circuit devices 1434 scans the pixel sensors 1414 line by line in the pixel sensor array 1406 for exposure until all of the pixel sensors 1414 are exposed. All actions are completed in a very short time, and the exposure time of different rows of pixel sensors 1414 is different. Therefore, the exposure operation may produce incomplete images and/or distortions when capturing fast-moving objects using such progressive exposure. This may result in deformed images due to the output time difference. The one or more trench capacitor structures 126 may enable global shutter functionality, in which all of the pixel sensors 1414 in the of the pixel sensor array 1406 are exposed simultaneously. At the start of the global shutter exposure operation, each pixel sensor 1414 simultaneously begins to collect charge and generate a photocurrent, and is allowed to do so for the duration of the exposure time of the global shutter exposure operation. Each pixel sensor 1414 transfers a photocurrent to the one or more trench capacitor structures 126 for accumulation simultaneously. At the end of the global shutter exposure operation, the one or more trench capacitor structures 126 transfer the photocurrents to the integrated circuit devices 1434.

As indicated above, FIG. 14 is provided as an example. Other examples may differ from what is described with regard to FIG. 14.

FIG. 15 is a diagram of an example semiconductor device 1500 described herein. The semiconductor device 1500 may include an example of a three-dimensional image sensor (e.g., a 3D CIS). The semiconductor device 1500 may be configured to be deployed in various implementations, such as digital cameras, video recorders, night-vision cameras, automotive sensors and cameras, and/or other types of light-sensing implementations.

As shown in FIG. 15, the semiconductor device 1500 includes a similar combination of structures and/or layers as the semiconductor device 1400. For example, the semiconductor device 1500 may include elements 1402a-1450 and one or more implementations of trench capacitor structures 126 illustrated and described herein.

However, as shown in FIG. 15, the semiconductor device 1500 the trench capacitor structures 126 are included in the second semiconductor die 1402b (e.g., an application-specific integrated circuit (ASIC) die) as opposed to (or in addition to) in the first semiconductor die 1402a (e.g., the sensor die). Including the one or more trench capacitor structures 126 on the second semiconductor die 1402b as opposed to the first semiconductor die 1402a enables a greater amount of the area in the first semiconductor die 1402a to be used for the photodiodes 1418 (which provides increased full well capacity for the photodiodes 1418) and/or for control circuitry of the pixel sensors 1414 (e.g., for the transfer gates 1422, the reset gates, the source follower gates), which may increase the performance of the semiconductor device 1500.

The one or more trench capacitor structures 126 may be included in the dielectric region 1438 of the interconnect layer 1436 of the second semiconductor die 1402b. The bottom electrode structure 204 of a trench capacitor structure 126 included in the interconnect layer 1436 of the second semiconductor die 1402b may include a plurality of columns 204a-204d that each include a vertically alternating arrangement of metallization structures 1440 and interconnect structures 1442. The columns 204a-204d define the trenches of the trench capacitor structure 126, and the insulator layer 208 may be formed on the sidewalls of the trenches (corresponding to the sidewalls of the columns 204a-204d).

As indicated above, FIG. 15 is provided as an example. Other examples may differ from what is described with regard to FIG. 15.

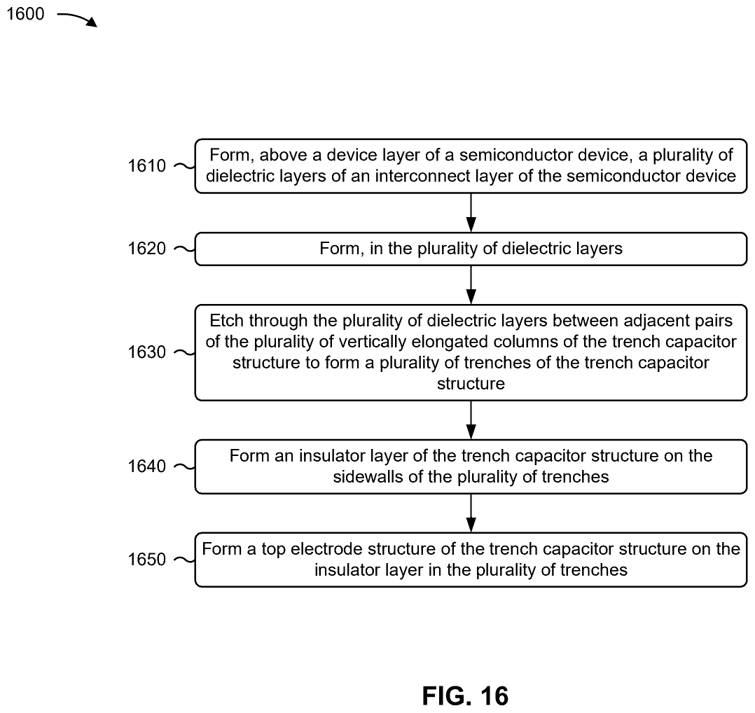

FIG. 16 is a flowchart of an example process 1600 associated with forming a capacitor structure described herein. In some implementations, one or more process blocks of FIG. 16 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 16, process 1600 may include forming, above a device layer of a semiconductor device, a plurality of dielectric layers of an interconnect layer of the semiconductor device (block 1610). For example, one or more semiconductor processing tools may be used to form, above a device layer (e.g., a device layer 102) of a semiconductor device (e.g., a semiconductor device 100), a plurality of dielectric layers (e.g., ILD layers 114a-114e, ESL layers 116a-116e) of an interconnect layer (e.g., an interconnect layer 104) of the semiconductor device, as described herein.

As further shown in FIG. 16, process 1600 may include forming, in the plurality of dielectric layers, a first plurality of backend conductive structures and a second plurality of backend conductive structures (block 1620). For example, one or more semiconductor processing tools may be used to form, in the plurality of dielectric layers, a first plurality of backend conductive structures (e.g., metallization structures 122, interconnect structures 124) and a second plurality of backend conductive structures (e.g., metallization structures 122, interconnect structures 124), as described herein. In some implementations, the second plurality of backend conductive structures are arranged in a plurality of vertically elongated columns (e.g., columns 204a-204d) that correspond to a bottom electrode structure (e.g., a bottom electrode structure 204) of a trench capacitor structure (e.g., a trench capacitor structure 126).

As further shown in FIG. 16, process 1600 may include etching through the plurality of dielectric layers between adjacent pairs of the plurality of vertically elongated columns of the trench capacitor structure to form a plurality of trenches of the trench capacitor structure (block 1630). For example, one or more semiconductor processing tools may be used to etch through the plurality of dielectric layers between adjacent pairs of the plurality of vertically elongated columns of the trench capacitor structure to form a plurality of trenches (e.g., trenches 202a-202c) of the trench capacitor structure, as described herein. In some implementations, the plurality of vertically elongated columns define sidewalls of the plurality of trenches.

As further shown in FIG. 16, process 1600 may include forming an insulator layer of the trench capacitor structure on the sidewalls of the plurality of trenches (block 1640). For example, one or more semiconductor processing tools may be used to form an insulator layer (e.g., an insulator layer 208) of the trench capacitor structure on the sidewalls of the plurality of trenches, as described herein.

As further shown in FIG. 16, process 1600 may include forming a top electrode structure of the trench capacitor structure on the insulator layer in the plurality of trenches (block 1650). For example, one or more semiconductor processing tools may be used to form a top electrode structure (e.g., a top electrode structure 206) of the trench capacitor structure on the insulator layer in the plurality of trenches, as described herein.

Process 1600 may include additional implementations, such as any single implementation or any combination of implementations described below and/or in connection with one or more other processes described elsewhere herein.

In a first implementation, the second plurality of backend conductive structures further includes a bottom conductive structure (e.g., a bottom conductive structure 204e), and forming the second plurality of backend conductive structures includes forming the plurality of vertically elongated columns on the bottom conductive structure.

In a second implementation, alone or in combination with the first implementation, forming the top electrode structure includes filling the plurality of trenches with material of the top electrode structure such that voids are formed in the top electrode structure in the plurality of trenches.

In a third implementation, alone or in combination with one or more of the first and second implementations, process 1600 includes planarizing the insulator layer and the top electrode structure after forming the top electrode structure such that the insulator layer is discontinuous between the plurality of trenches.

In a fourth implementation, alone or in combination with one or more of the first through third implementations, forming the insulator layer includes forming a first low-k dielectric layer (e.g., a dielectric layer 208a), forming a high-k dielectric layer (e.g., a dielectric layer 208b) on the first low-k dielectric layer, and forming a second low-k dielectric layer (e.g., a dielectric layer 208c) on the high-k dielectric layer.

In a fifth implementation, alone or in combination with one or more of the first through fourth implementations, process 1600 includes forming a plurality of top contact structures (e.g., top interconnect structures 130a-130c) on the top electrode structure, where each top contact structure, of the plurality of top contact structures, is formed directly above a trench of the plurality of trenches.

Although FIG. 16 shows example blocks of process 1600, in some implementations, process 1600 includes additional blocks, fewer blocks, different blocks, or differently arranged blocks than those depicted in FIG. 16. Additionally, or alternatively, two or more of the blocks of process 1600 may be performed in parallel.

In this way, one or more trench capacitor structures are included in an interconnect layer of a semiconductor device. The processing operations for forming the trench capacitor structures described herein may integrated into the processing operations for forming the interconnect layer. As an example, a plurality of columns (or “fingers”) of a bottom electrode structure of a trench capacitor structure described herein may be built up as a combination of backend conductive structures (e.g., interconnect structures and metallization structures) in the interconnect layer. Portions of ILD layers of the interconnect layer between the columns of the bottom electrode structure are removed to form the trenches of the trench capacitor structure, where the columns define the trenches. In this way, the columns of the bottom electrode structure function as a self-aligned mask for forming the trenches of the structure and enable a high aspect ratio be achieved for the trench capacitor structure. The deep trenches may then be lined with a conformal insulator layer and filled with the top electrode structure of the trench capacitor structure.

As described in greater detail above, some implementations described herein provide a semiconductor structure. The semiconductor structure includes a bottom electrode structure comprising a plurality of columns of backend conductive structures of an interconnect layer in a semiconductor device, where the plurality of columns of backend conductive structures define a plurality of trenches of the semiconductor structure. The semiconductor structure includes an insulator layer on sidewalls and bottom surfaces of the plurality of trenches. The semiconductor structure includes a top electrode structure on the insulator layer in the plurality of trenches.

As described in greater detail above, some implementations described herein provide a semiconductor structure. The capacitor structure includes a bottom electrode structure that includes a plurality of columns of backend conductive structures of an interconnect layer in a semiconductor device, where the plurality of columns of backend conductive structures define a plurality of trenches of the semiconductor structure, and where each column of backend conductive structures, of the plurality of columns of backend conductive structures, includes an alternating arrangement of vias and metallization structures. The semiconductor structure includes an insulator layer on sidewalls and bottom surfaces of the plurality of trenches. The semiconductor structure includes a top electrode structure on the insulator layer in the plurality of trenches, where the top electrode structure comprises airgaps that extend into the plurality of trenches.

As described in greater detail above, some implementations described herein provide a method. The method includes forming, above a device layer of a semiconductor device, a plurality of dielectric layers of an interconnect layer of the semiconductor device. The method includes forming, in the plurality of dielectric layers, a first plurality of backend conductive structures and a second plurality of backend conductive structures, where the second plurality of backend conductive structures are arranged in a plurality of vertically elongated columns that correspond to a bottom electrode structure of a trench capacitor structure. The method includes etching through the plurality of dielectric layers between adjacent pairs of the plurality of vertically elongated columns of the trench capacitor structure to form a plurality of trenches of the trench capacitor structure, where the plurality of vertically elongated columns define sidewalls of the plurality of trenches. The method includes forming an insulator layer of the trench capacitor structure on the sidewalls of the plurality of trenches. The method includes forming a top electrode structure of the trench capacitor structure on the insulator layer in the plurality of trenches.

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a bottom electrode structure comprising a plurality of columns of backend conductive structures of an interconnect layer in a semiconductor device,
wherein the plurality of columns of backend conductive structures define a plurality of trenches of the semiconductor structure;
an insulator layer on sidewalls and bottom surfaces of the plurality of trenches; and
a top electrode structure on the insulator layer in the plurality of trenches.

2. The semiconductor structure of claim 1, wherein the bottom electrode structure further comprises:
an horizontally elongated conductive structure under the plurality of columns of backend conductive structures and under the plurality of trenches,
wherein the horizontally elongated conductive structure laterally spans the plurality of columns of backend conductive structures and the plurality of trenches.

3. The semiconductor structure of claim 2, further comprising:
a bottom contact structure under the horizontally elongated conductive structure,
wherein the bottom contact structure is coupled to the horizontally elongated conductive structure, and
wherein the bottom contact structure is coupled to a transistor structure in a device layer of the semiconductor device under the interconnect layer.

4. The semiconductor structure of claim 1, wherein the insulator layer continuously extends between the plurality of trenches.

5. The semiconductor structure of claim 1, wherein the insulator layer comprises a plurality of discontinuous segments,
wherein each segment of the plurality of discontinuous segments is included in a trench of the plurality of trenches.

6. The semiconductor structure of claim 1, wherein the top electrode structure comprises a merged section above the plurality of trenches; and
wherein the merged section is coupled to a top contact structure of the semiconductor structure.

7. The semiconductor structure of claim 1, wherein the top electrode structure comprises a plurality of discontinuous columns,
wherein each column of the plurality of discontinuous columns is included in a trench of the plurality of trenches; and
wherein each column of the plurality of discontinuous columns is coupled to a respective top contact structure of the semiconductor structure.

8. A semiconductor structure, comprising:
a bottom electrode structure comprising a plurality of columns of backend conductive structures of an interconnect layer in a semiconductor device,
wherein the plurality of columns of backend conductive structures define a plurality of trenches of the semiconductor structure, and
wherein each column of backend conductive structures, of the plurality of columns of backend conductive structures, includes an alternating arrangement of interconnect structures and metallization structures;
an insulator layer on sidewalls and bottom surfaces of the plurality of trenches; and
a top electrode structure on the insulator layer in the plurality of trenches,
wherein the top electrode structure comprises airgaps that extend into the plurality of trenches.

9. The semiconductor structure of claim 8, wherein the interconnect structures have tapered sidewalls.

10. The semiconductor structure of claim 8, wherein the insulator layer comprises a multiple-layer stack comprising:
a first low dielectric constant (low-k) dielectric layer;
a high dielectric constant (high-k) dielectric layer on the first low-k dielectric layer; and
a second low-k dielectric layer on the high-k dielectric layer.

11. The semiconductor structure of claim 8, wherein the interconnect structures have approximately parallel sidewalls.

12. The semiconductor structure of claim 8, further comprising:
first respective contact structures coupled to each of the plurality of columns of backend conductive structures; and
second respective contact structures coupled to the top electrode structure in each of the plurality of trenches.

13. The semiconductor structure of claim 12, further comprising:
a first horizontally elongated conductive structure above and coupled to each of the first respective contact structures; and
a second horizontally elongated conductive structure above and coupled to each of the second respective contact structures.

14. The semiconductor structure of claim 12, wherein the bottom electrode structure further comprises:
a first horizontally elongated conductive structure under the plurality of columns of backend conductive structures and under the plurality of trenches,
wherein the first horizontally elongated conductive structure laterally spans the plurality of columns of backend conductive structures and the plurality of trenches; and
wherein the semiconductor structure further comprises:
a bottom contact structure under the first horizontally elongated conductive structure,
wherein the bottom contact structure is coupled to the first horizontally elongated conductive structure;
respective second contact structures coupled to the top electrode structure in each of the plurality of trenches; and
a second horizontally elongated conductive structure above and coupled to each of the respective second contact structures.

15. A method, comprising:
forming, above a device layer of a semiconductor device, a plurality of dielectric layers of an interconnect layer of the semiconductor device;
forming, in the plurality of dielectric layers:
a first plurality of backend conductive structures; and
a second plurality of backend conductive structures,
wherein the second plurality of backend conductive structures are arranged in a plurality of vertically elongated columns that correspond to a bottom electrode structure of a trench capacitor structure;
etching through the plurality of dielectric layers between adjacent pairs of the plurality of vertically elongated columns of the trench capacitor structure to form a plurality of trenches of the trench capacitor structure,
wherein the plurality of vertically elongated columns define sidewalls of the plurality of trenches;
forming an insulator layer of the trench capacitor structure on the sidewalls of the plurality of trenches; and
forming a top electrode structure of the trench capacitor structure on the insulator layer in the plurality of trenches.

16. The method of claim 15, wherein the second plurality of backend conductive structures further comprise a bottom conductive structure; and
wherein forming the second plurality of backend conductive structures comprises:
forming the plurality of vertically elongated columns on the bottom conductive structure.

17. The method of claim 15, wherein forming the top electrode structure comprises:
filling the plurality of trenches with material of the top electrode structure such that voids are formed in the top electrode structure in the plurality of trenches.

18. The method of claim 15, further comprising:
planarizing the insulator layer and the top electrode structure after forming the top electrode structure such that the insulator layer is discontinuous between the plurality of trenches.

19. The method of claim 15, wherein forming the insulator layer comprises:
forming a first low dielectric constant (low-k) dielectric layer;
forming a high dielectric constant (high-k) dielectric layer on the first low-k dielectric layer; and
forming a second low-k dielectric layer on the high-k dielectric layer.

20. The method of claim 15, further comprising:
forming a plurality of top contact structures on the top electrode structure,
wherein each top contact structure, of the plurality of top contact structures, is formed directly above a trench of the plurality of trenches.
